(19) United States
(12) Patent Application Publication
(10) Pub. No.: US 2025/0151445 A1
(43) Pub. Date: May 8, 2025

(54) IMAGE SENSOR

(71) Applicant: Samsung Electronics Co., Ltd., Suwon-si (KR)

(72) Inventors: Ingyu BAEK, Suwon-si (KR); Jinmyoung LEE, Suwon-si (KR); Soonhyung HONG, Suwon-si (KR)

(73) Assignee: Samsung Electronics Co., Ltd., Suwon-si (KR)

(21) Appl. No.: 18/742,302

(22) Filed: Jun. 13, 2024

(30) Foreign Application Priority Data
Nov. 2, 2023 (KR) 10-2023-0150172

(51) Int. Cl. H01L 27/146

(52) U.S. Cl. CPC H10F 39/811; H10F 39/80373

(57) ABSTRACT

An image sensor that includes a first layer and a second layer bonded to the first layer. The first layer includes a first substrate including a first front surface and a first back surface, a floating diffusion region formed in the first substrate, a first pad, and a first conductive line provided between the floating diffusion region and the first pad. The second layer includes a second substrate including a second front surface and a second back surface, pixel transistors formed on the second substrate, a second pad, and a second conductive line provided between one of the pixel transistors and the second pad. The second conductive line passes through the second substrate and is electrically connected to a lower portion of the pixel transistor.

### CROSS-REFERENCE TO RELATED APPLICATIONS

The application claims benefit of priority under 35 U.S.C. § 119 to Korean Patent Application No. 10-2023-0150172, filed on Nov. 2, 2023, in the Korean Intellectual Property Office, the disclosure of which is incorporated by reference herein in their entireties.

### BACKGROUND

The present disclosure relates generally to an image sensor.

Image sensors are devices that convert optical image signals into electrical signals, and include charge coupled device (CCD) image sensors and complementary metal oxide semiconductor (CMOS) image sensors. The image sensor includes a plurality of pixels. Each pixel includes a light-receiving area that receives incident light and converts it into an electrical signal, and a pixel circuit that outputs a pixel signal using charges generated in the light-receiving area.

Recently, as the integration of image sensors has increased, the size of each pixel is becoming smaller. There is a problem that image transmission delay occurs depending on the arrangement and shape of components within a pixel, thereby deteriorating the quality of the image sensor.

### SUMMARY

Some example embodiments of the present disclosure provide an image sensor with size that is reduced (and/or minimized).

Example embodiments of the inventive concepts provide an image sensor that includes a first layer including a first substrate having a first front surface and a first back surface opposite the first front surface, a floating diffusion region in the first substrate, a first pad, and a first conductive line connecting the floating diffusion region and the first pad; and a second layer including a second substrate having a second front surface and a second back surface opposite the second front surface, pixel transistors on the second substrate, a second pad, and a second conductive line connecting one of the pixel transistors and the second pad. The second layer is bonded to the first layer. The second conductive line passes through the second substrate and is electrically connected to a lower portion of the pixel transistor.

Example embodiments of the inventive concepts further provide an image sensor that includes a pixel array including a plurality of pixels. The plurality of pixels include a first pixel and a second pixel adjacent to each other. Each of the first pixel and the second pixel includes a first layer and a second layer bonded to the first layer. The first layer includes a first substrate having a first front surface and a first back surface opposite the first front surface, a floating diffusion region in the first substrate, at least one first pad, and a first conductive line connecting the floating diffusion region and the at least one first pad. The second layer includes a second substrate having a second front surface and a second back surface opposite the second front surface, pixel transistors on the second substrate, a second pad, and a second conductive line connecting one of the pixel transistors and the second pad. The second conductive line passes through the second substrate and is electrically connected to a lower portion of the one of the pixel transistors.

Example embodiments of the inventive concepts still further provide an image sensor that includes a pixel array region and a pad region. Each of the pixel array region and the pad region includes a first layer and a second layer bonded to the first layer. In the pixel array region the first layer includes a first substrate having a first front surface and a first back surface opposite the first front surface, a floating diffusion region in the first substrate, a first pad, and a first conductive line connecting the floating diffusion region and the first pad. In the pixel array region the second layer includes a second substrate having a second front surface and a second back surface opposite the second front surface, pixel transistors on the second substrate, a second pad, and a second conductive line connecting one of the pixel transistors and the second pad, the second conductive line passing through the second substrate and being electrically connected to a lower portion of the pixel transistor. In the pad region, the first layer includes a main via penetrating the first substrate, and a signal pad on the main via.

Additional aspects will be set forth in part in the description which follows and, in part, will be apparent from the description, or may be learned by practice of the example embodiments.

### BRIEF DESCRIPTION OF DRAWINGS

The above and other aspects, features, and advantages of some example embodiments of the present disclosure will be more apparent from the following description taken in conjunction with the accompanying drawings, in which:

FIG. 1 is a block diagram of an image sensor according to some example embodiments of the inventive concepts.

FIG. 2 is a circuit diagram of a pixel in an image sensor according to some example embodiments of the inventive concepts.

FIG. 3 is a diagram conceptually showing the layout of an image sensor according to some example embodiments of the inventive concepts.

FIG. 4 is a plan view showing the image sensor of FIG. 3.

FIG. 5 is a cross-sectional view of an image sensor according to some example embodiments.

FIG. 6 is an enlarged view of portion AA of FIG. 5.

FIG. 7 is a cross-sectional view of an image sensor according to some example embodiments.

FIG. 8 is a cross-sectional view of an image sensor according to some example embodiments.

FIG. 9 is a cross-sectional view of an image sensor according to some example embodiments.

FIG. 10 is a cross-sectional view of an image sensor according to some example embodiments.

FIG. 11 is a cross-sectional view of an image sensor according to some example embodiments.

FIG. 12 is a cross-sectional view of an image sensor according to some example embodiments.

FIG. 13 is a cross-sectional view of an image sensor according to some example embodiments.

FIG. 14 is a flowchart for explaining a manufacturing method of the first layer of FIG. 10.

FIGS. 15, 16 and 17 are drawings for explaining a manufacturing method of FIG. 14.

FIG. 18 is a flowchart for explaining a manufacturing method of the second layer of FIG. 10.

FIGS. 19, 20 and 21 are drawings for explaining a manufacturing method of FIG. 18.

FIG. 22 is a flowchart for explaining a manufacturing method of the third layer of FIG. 10.

FIGS. 23 and 24 are drawings for explaining a manufacturing method of FIG. 22.

FIG. 25 is a flowchart for explaining a method of manufacturing the bonded second and third layers of FIG. 10.

FIGS. 26, 27, 28 and 29 are drawings for explaining a manufacturing method of FIG. 24.

FIG. 30 is a flowchart for explaining a method of manufacturing the bonded first to third layers of FIG. 10.

FIG. 31 is a diagram for explaining the manufacturing method of FIG. 30.

### DETAILED DESCRIPTION

Hereinafter, some example embodiments of the present disclosure will be described in detail and clearly to such an extent that one of ordinary skill in the art may easily implement the inventive concepts.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

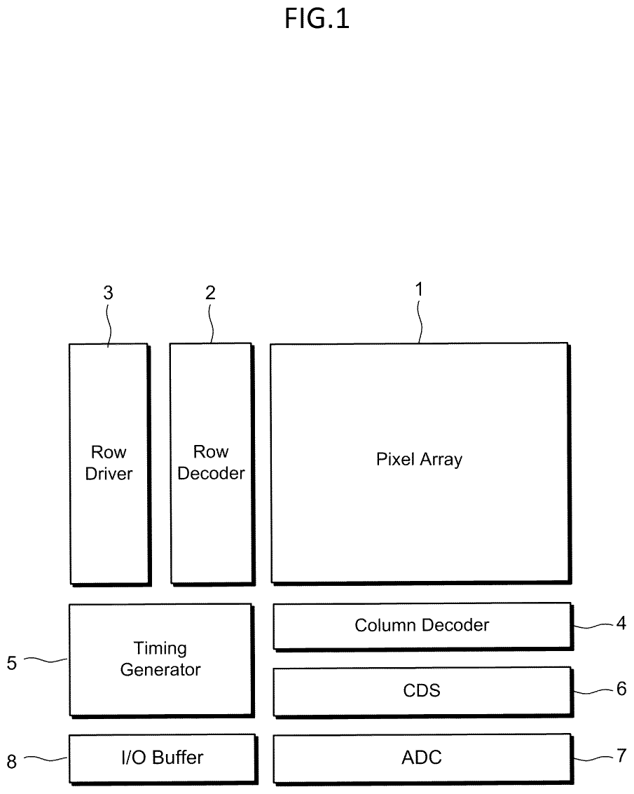

FIG. 1 is a block diagram of an image sensor according to some example embodiments of the inventive concepts.

Referring to FIG. 1, the image sensor according to some example embodiments of the inventive concepts may include a pixel array 1, row decoder 2, row driver 3, column decoder 4, timing generator 5, correlated double sampler (CDS) 6, Analog to Digital Converter (ADC) 7, and I/O buffer 8.

The pixel array 1 may include a plurality of unit pixels arranged two-dimensionally and converts optical signals into electrical signals. The pixel array 1 may be driven by a plurality of driving signals such as a pixel selection signal, a reset signal, and a charge transfer signal provided from the row driver 3. Additionally, the converted electrical signal may be provided to the correlated double sampler 6.

The row driver 3 may provide a plurality of driving signals for driving a plurality of unit pixels to the pixel array 1 according to the results decoded by the row decoder 2. When unit pixels may be arranged in a matrix, driving signals may be provided for each row.

The timing generator 5 may provide timing signals and control signals to the row decoder 2 and column decoder 4.

The correlated double sampler 6 may receive, hold, and sample the electrical signal generated by the pixel array 1. The correlated double sampler 6 may sample a specific noise level and a signal level caused by an electrical signal and outputs a difference level corresponding to the difference between the noise level and the signal level.

The analog-to-digital converter 7 may convert the analog signal corresponding to the difference level output from the correlated double sampler 6 into a digital signal and outputs it.

The I/O buffer 8 may latch the digital signal, and sequentially may output the digital signal to the video signal processor (not shown) according to the decoding result in the column decoder 4.

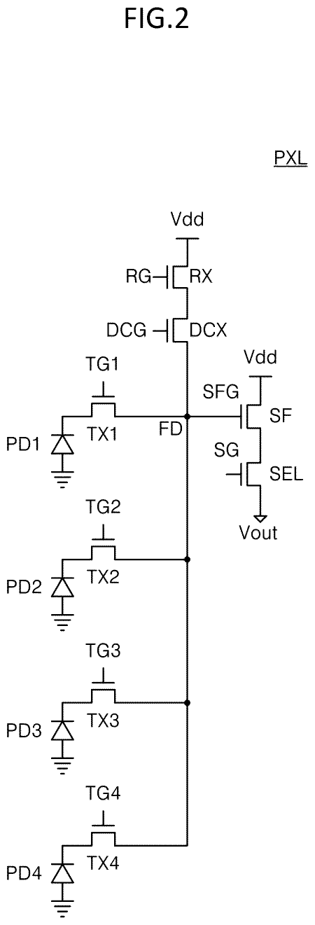

FIG. 2 is a circuit diagram of a pixel in an image sensor according to some example embodiments of the inventive concepts.

Referring to FIG. 2, the pixel PXL may include photoelectric conversion elements PD1, PD2, PD3, and PD4, a floating diffusion region FD, and pixel transistors. The pixel transistors may include a transfer transistor TX1, TX2, TX3, and TX4, a reset transistor RX, a source follower transistor SF, and a selection transistor SEL, and a dual conversion gain transistor DCX.

As an example, the pixel PXL may be disclosed as including four transfer transistors TX1, TX2, TX3, and TX4 and four photoelectric conversion elements PD1, PD2, PD3, and PD4. In some example embodiments, the pixel PXL may include fewer or more than four transfer transistors and photoelectric conversion elements. A photoelectric conversion device PD may generate and accumulate charges corresponding to incident light. The photoelectric conversion elements PD1, PD2, PD3, and PD4 may include, for example, a photo diode, a photo transistor, a photo gate, a pinned photo diode, or a combination thereof.

The transfer transistor TX1, TX2, TX3, and TX4 may be configured to transfer charges accumulated in the photoelectric conversion element PD1, PD2, PD3, and PD4 to the floating diffusion region FD according to a transfer signal applied to the transfer gate TG1, TG2, TG3, and TG4. The sources of the transfer transistors TX1, TX2, TX3, and TX4 may be electrically connected to the corresponding photoelectric conversion elements PD1, PD2, PD3, and PD4. The drains of the transfer transistors TX1, TX2, TX3, and TX4 may be electrically connected to the floating diffusion region FD.

The floating diffusion region FD may be configured to accumulate charges transferred from the photoelectric conversion elements PD1, PD2, PD3, and PD4. The source follower transistor SF may be controlled according to the amount of photocharges accumulated in the floating diffusion region FD.

The reset transistor RX may be configured to reset charges accumulated in the floating diffusion region FD according to a reset signal applied to the reset gate RG. The drain of the reset transistor RX may be electrically connected to the source of the double conversion gain transistor DCX. The source of the reset transistor RX may be connected to the pixel power voltage Vdd. When the reset transistor RX and the double conversion gain transistor DCX may be turned on, the pixel power voltage Vdd may be transferred to the floating diffusion region FD. Accordingly, the charges accumulated in the floating diffusion region FD may be discharged and the floating diffusion region FD may be reset.

The dual conversion gain transistor DCX may be provided between the floating diffusion region FD and the reset transistor RX. The drain of the double conversion gain transistor DCX may be electrically connected to the floating diffusion region FD. The double conversion gain transistor DCX may adjust the capacitance of the floating diffusion region FD according to the double conversion gain control signal applied to the reset gate RG. When the double conversion gain transistor DCX may be turned off while the reset transistor RX may be turned off, the drain of the double conversion gain transistor DCX may be the floating diffusion region FD. Accordingly, the floating diffusion region FD may have a relatively small first capacitance. When the double conversion gain transistor DCX may be turned on while the reset transistor RX may be turned off, the floating diffusion region FD may extend to the drain of the reset transistor RX. Accordingly, the floating diffusion region FD may have a relatively large second capacitance. In some example embodiments, the difference between the second capacitance and the first capacitance may be caused by the natural capacitance of the conductive line between the drain of the reset transistor RX and the source of the dual conversion gain transistor DCX. In some example embodiments, the difference between the second capacitance and the first capacitance may be caused by a capacitor placed on a conductive line branching from the conductive line between the drain of the reset transistor RX and the source of the dual conversion gain transistor DCX. As the capacitance of the floating diffusion region FD may be adjusted, the conversion gain of the pixel PXL may change.

The dual conversion gain transistor DCX may be configured to change the capacitance of the floating diffusion region FD based on the illumination environment. Accordingly, the conversion gain of the pixel PXL may be adjusted according to the illumination environment. When the dual conversion gain transistor DCX may be turned off, the pixel PXL may have a first conversion gain. When the dual conversion gain transistor DCX may be turned on, the pixel PXL may have a second conversion gain that may be lower than the first conversion gain. Depending on the operation of the dual conversion gain transistor DCX, different conversion gains may be provided in the first conversion gain mode (or low light mode) and the second conversion gain mode (or high light mode).

The source follower transistor SF may be configured to output a sampling voltage corresponding to the amount of charge in the floating diffusion region FD. For example, the source follower transistor SF may be a source follower buffer amplifier that generates a source-drain current in proportion to the amount of charge in the floating diffusion region FD input to the source follower gate SFG. The source follower transistor SF may be configured to amplify the potential change in the floating diffusion region FD and output the amplified sampling voltage to the output line Vout through the selection transistor SEL. The drain of the source follower transistor SF may be connected to the pixel power voltage Vdd, and the source of the source follower transistor SF may be electrically connected to the input node of the selection transistor SEL.

The selection transistor SEL may be configured to output a sampling voltage to the output node. The selection transistor SEL may select unit pixels to be read row by row. When the selection transistor SEL may be turned on by a selection signal applied to the gate of the selection transistor, the selection transistor SEL may output an electrical signal output to the source of the source follower transistor SF to the output line Vout.

In some example embodiments of the inventive concepts, the pixel PXL may be implemented on at least one structure including a semiconductor substrate. A structure may consist of one structure or multiple structures. Multiple structures can be stacked sequentially.

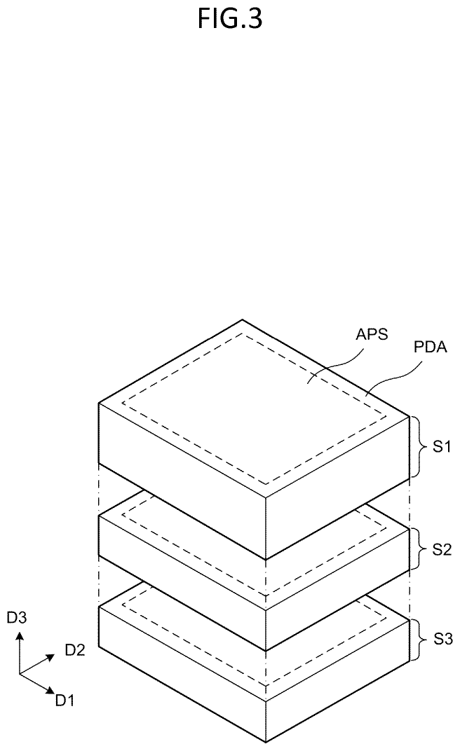

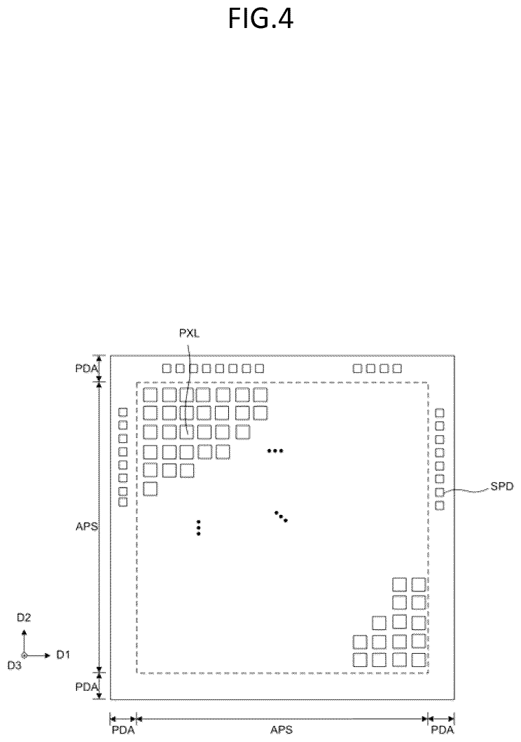

FIG. 3 is a diagram conceptually showing the layout of an image sensor according to some example embodiments of the inventive concepts. FIG. 4 is a plan view showing the image sensor of FIG. 3.

Referring to FIGS. 3 and 4, the image sensor may include a plurality of structures sequentially stacked in one direction. For example, the image sensor may include first to third structures S1, S2, and S3 stacked along the third direction D3. A plurality of structures may be provided in the form of a chip, and the size of each structure may be the same or different from each other. The first direction D1 and the second direction D2 may be two directions that intersect each other on a plane perpendicular to the third direction D3. The first to third structures S1, S2, and S3 may include a pixel array region APS and a pad region PDA adjacent to the pixel array region APS. For example, when viewed along the third direction D3, the pixel array region APS may be disposed at the center of the image sensor. The pixel array region APS may include a plurality of pixels PXL. The pixels PXL may detect incident light and output a photoelectric signal. Pixels PXL may form rows and columns arranged two-dimensionally. For example, within each row, pixels PXL may be arranged along the first direction D1. For example, within each of the columns, pixels PXL may be arranged along the second direction D2.

The pad region PDA may be located at the edge of the image sensor. The pad region PDA may be provided in at least one of the first to third structures S1 to S3. From a perspective along the third direction D3, the pad region PDA may surround the pixel array region APS. Signal pads SPD may be provided on the pad region PDA. The signal pads SPD may output electrical signals generated from the pixels PXL to the outside. Alternatively, an external electrical signal or voltage may be transmitted to the pixels PXL through the signal pads SPD. Since the pad region PDA may be an edge region of the image sensor, the signal pads SPD may be easily connected to the outside.

In some example embodiments of the inventive concepts, components within one pixel may be provided in different structures and connected to each other. Some components may be provided to the first structure (S1), other components may be provided to the second structure (S2), and the remaining structures may be provided to the third structure (S3). For example, a photoelectric conversion element, a transfer transistor, and a floating diffusion region may be provided in the first structure S1. For example, pixel transistors (e.g., reset transistor, source follower transistor, select transistor, and dual conversion gain transistor) may be provided in the second structure S2. For example, logic circuits including logic transistors may be provided in the third structure S3. The logic circuits may include circuits for processing pixel signals from pixels. For example, the logic circuits may include a control register block, timing generator, row driver, read-out circuit, ramp signal generator, image signal processor, etc.

In some example embodiments of the inventive concepts, memory elements may be further disposed in the second and/or third structures S2 and S3. For example, memory devices may include dynamic random access memory (DRAM) devices, static random access memory (SRAM) devices, spin transfer torque magnetic random access memory (STT-MRAM) devices, or flash memory devices. In some example embodiments, the memory element may be formed in an embedded form. By using these memory elements to temporarily store frame images and perform signal processing, the image sensor may reduce (and/or minimize) the zello effect and improve the operating characteristics of the image sensor. Additionally, the memory element of the image sensor may be formed together with the logic elements in an embedded form, thereby simplifying the manufacturing process and reducing the size of the product.

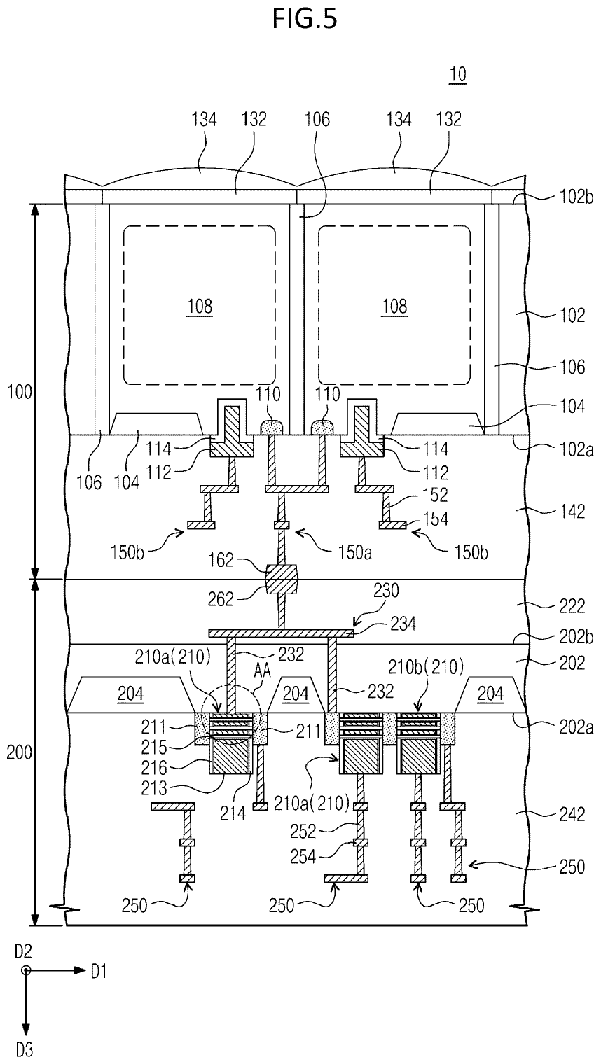

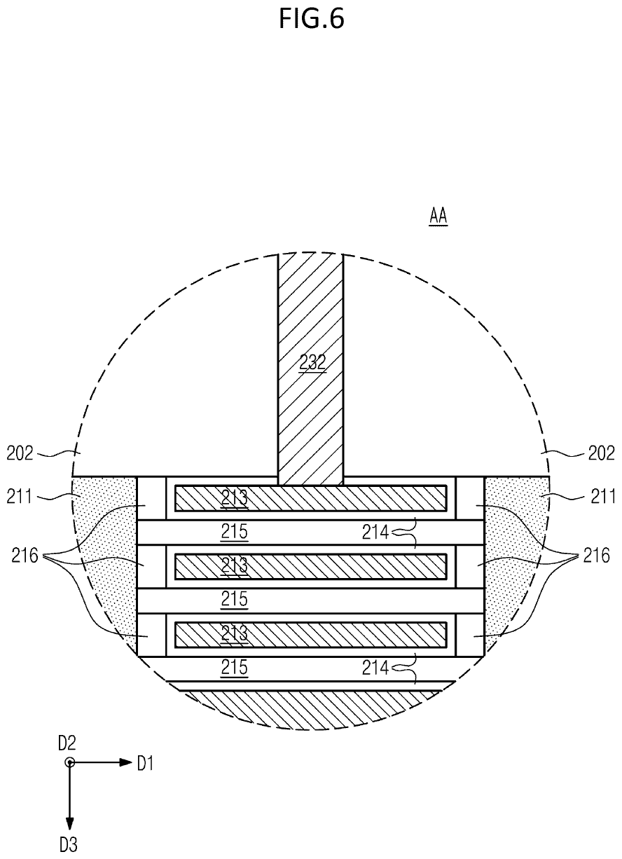

FIG. 5 is a cross-sectional view of an image sensor according to some example embodiments. FIG. 6 is an enlarged view of portion AA of FIG. 5.

Referring to FIGS. 5 and 6, a first layer 100 and a second layer 200 arranged along the third direction D3 may be provided. In some example embodiments, the first layer 100 and the second layer 200 may be the first structure S1 and the second structure S2 respectively described with reference to FIG. 3. The first layer 100 and the second layer 200 may be configured to be bonded to each other. For example, the first layer 100 and the second layer 200 may be bonded by copper (Cu)—copper (Cu) bonding.

The first layer 100 may include a first substrate 102. The first substrate 102 may be a semiconductor substrate. For example, the first substrate 102 may include silicon (Si), germanium (Ge), or silicon-germanium (SiGe). The first substrate 102 may include a first front surface 102a and a first back surface 102b facing opposite directions. The first front surface 102a and the first back surface 102b may extend along the first direction D1 and the second direction D2. The first front surface 102a and the first back surface 102b may be spaced apart from each other along the third direction D3. The third direction D3 may be perpendicular to the first direction D1 and the second direction D2. The first substrate 102 may have a first conductivity type. For example, the first conductivity type may be p-type or n-type. When the conductivity type of the first substrate 102 may be p-type, the first substrate 102 may be a silicon (Si) first substrate containing Group 3 element or Group 2 elements as an impurities. For example, Group 3 elements may include boron (B), aluminum (Al), gallium (Ga), indium (In), etc. When the conductivity type of the first substrate 102 may be n-type, the first substrate 102 may be a silicon (Si) substrate containing Group 5, 6, or 7 elements as impurities. For example, group 5 elements may include phosphorus (P), arsenic (As), antimony (Sb), etc. Hereinafter, the region where the conductivity type may be n-type may include impurities of group 5, 6, or 7 elements. Hereinafter, impurities that cause the first substrate 102 to have the first conductivity type and a second conductivity type may be referred to as first impurities and second impurities, respectively. When the first conductivity type may be p-type or n-type, the second conductivity type may be n-type or p-type, respectively. The first substrate 102 may be an epi layer formed through an epitaxial growth process. For brevity of explanation, hereinafter the first conductivity type may be described as p-type, and the second conductivity type may be described as n-type.

The first layer 100 may include a first device isolation layer 104. A first device isolation layer 104 may be provided on the first substrate 102. The first device isolation layer 104 may define an active region. The active region may be a region provided with a transmission gate electrode 112, a transmission gate insulating layer 114, and a floating diffusion region 110, which is described below. From a plan view, the first device isolation layer 104 may surround the active region. The first device isolation layer 104 may have a thickness along the third direction D3. The thickness of the first device isolation layer 104 may be smaller than the thickness of the pixel isolation layer described below. For example, the first device isolation layer 104 may be a shallow trench isolation STI layer. In some example embodiments, one surface of the first device isolation layer 104 may be located at substantially the same level as the first front surface 102a. The first device isolation layer 104 may include silicon nitride, silicon oxide, silicon oxynitride, or a combination thereof.

The first layer 100 may include a pixel isolation layer 106. A pixel isolation layer 106 may be provided between the pixels PXL. The pixel separator 106 may extend along the third direction D3. In some example embodiments, both surfaces spaced apart from each other along the third direction D3 of the pixel separator 106 may be positioned at substantially the same level as the first front surface 102a and the first back surface 102b, respectively. The pixel separator 106 may prevent or reduce the electric crosstalk phenomenon that reduces the signal-to-noise ratio by exchanging charge carriers between adjacent pixels PXL. For example, the pixel separator 106 may include a conductive material, an insulating material, or a high dielectric material. The conductive material may include, for example, at least one of doped polysilicon, metal, metal silicide, metal nitride, or metal-containing material. The insulating material may include, for example, a silicon-based insulating material (e.g., silicon nitride, silicon oxide, and/or silicon oxynitride). The high dielectric material may include, for example, a metal oxide containing at least one metal selected from the group consisting of hafnium, zirconium, aluminum, tantalum, titanium, yttrium, and lanthanoid. In some example embodiments, the sidewall of the pixel separator 106 may be doped with a highly reflective material to prevent or reduce the optical crosstalk phenomenon in which light may be detected not at the incident pixel but at an adjacent pixel. For example, a highly reflective material may be boron. When the pixel separator 106 may include a conductive material, in some example embodiments, a negative fixed charge layer may be provided between the pixel separator 106 and the first substrate 102. The negative fixed charge layer may include, for example, a metal oxide containing at least one metal selected from the group consisting of hafnium, zirconium, aluminum, tantalum, titanium, yttrium, and lanthanoids. However, the structure of the pixel isolation layer 106 may be determined as needed. In some example embodiments, the pixel isolation layer 106 may be an insulating layer having a single structure. In some example embodiments, the pixel isolation layer 106 may include a plurality of insulating layers.

The first layer 100 may include a photoelectric conversion region 108. The photoelectric conversion region 108 may be provided within the first substrate 102. The photoelectric conversion regions 108 may be disposed in each of the pixels PXL. In some example embodiments, the photoelectric conversion region 108 may include at least one photodiode. For example, the photoelectric conversion region 108 may include a pn photodiode. In some example embodiments, the p-type region of the photoelectric conversion region 108 may be the first substrate 102, and the n-type region may be formed by implanting a second impurity into the first substrate 102. In some example embodiments, the p-type region may be formed by implanting a first impurity into the first substrate 102. In some example embodiments, the doping concentration of the p-type region may be higher than that of the first substrate 102. In some example embodiments, first impurities may be further implanted into the first substrate 102 to form a plurality of pn junctions located at different depths. In some example embodiments, the photoelectric conversion region 108 may include a photodiode. In some example embodiments, photoelectric conversion region 108 may include phototransistors, photogates, or pinned photodiodes. When light may be incident on the photoelectric conversion region 108, an electron-hole pair (EHP) may be generated in the photoelectric conversion region 108. For example, electron-hole pairs may be created in a depletion region formed in a region adjacent to the pn junction. Since the depth at which light penetrates the first substrate 102 varies depending on the wavelength, when a plurality of pn junctions located at different depths may be used, lights having different wavelengths may be efficiently detected. The stronger the intensity of light incident on the photoelectric conversion region 108, the more electron-hole pairs may be generated. When a reverse bias may be applied to the photoelectric conversion region 108, charge carriers (electrons or holes) may be accumulated in the photoelectric conversion region 108. Charge carriers accumulated in the photoelectric conversion region 108 may move to the floating diffusion region 110 by the voltage applied to the transfer gate electrode 112.

The first layer 100 may include the floating diffusion region 110. The floating diffusion region 110 may be provided within the first substrate 102. The floating diffusion region 110 may be provided in a region adjacent to the first front surface 102a. The floating diffusion region 110 may have a second conductivity type. In some example embodiments, the floating diffusion region 110 may be formed by implanting second impurities into the first substrate 102. The floating diffusion region 110 may be spaced apart from the photoelectric conversion region 108. The region between the floating diffusion region 110 and the photoelectric conversion region 108 (that is, one region of the first substrate 102) may have the first conductivity type. The floating diffusion region 110 may receive and accumulate charge carriers provided from the photoelectric conversion region 108.

The first layer 100 may include a transmission gate electrode 112. The transmission gate electrode 112 may be provided adjacent to the floating diffusion region 110 and the photoelectric conversion region 108. The transmission gate electrode 112 may be inserted into the first substrate 102. In some example embodiments, one portion of the transfer gate electrode 112 may protrude onto the first front surface 102a, and the other portion may be inserted into the first substrate 102. The transmission gate electrode 112 may extend along the third direction D3. The transmission gate electrode 112 may include an electrically conductive material. For example, the transmission gate electrode 112 may include doped polysilicon or metal. For example, the metal may include copper (Cu), aluminum (Al), molybdenum (Mo), platinum (Pt), titanium (Ti), tantalum (Ta), tungsten (W), or combinations thereof. The transfer gate electrode 112 may be referred to as a vertical transfer gate VTG.

The first layer 100 may include a transmission gate insulating layer 114. The transmission gate insulating layer 114 may be provided between the transmission gate electrode 112 and the first substrate 102. The transmission gate insulating layer 114 may extend along the surface of the transmission gate electrode 112. The transmission gate insulating layer 114 may be configured to electrically separate the transmission gate electrode 112 and the first substrate 102. For example, the transmission gate insulating layer 114 may include a silicon-based insulating material or a high dielectric material. For example, the silicon-based insulating material may include, for example, silicon nitride, silicon oxide, and/or silicon oxynitride. For example, the high dielectric material may include a metal oxide containing at least one metal selected from the group consisting of hafnium (Hf), zirconium (Zr), aluminum (Al), tantalum (Ta), titanium (Ti), yttrium (Y), and lanthanoid (La).

The transfer gate electrode 112, the transfer gate insulating layer 114, the photoelectric conversion region 108, and the floating diffusion region 110 may form a transfer transistor. The transfer gate electrode 112, the photoelectric conversion region 108, and the floating diffusion region 110 may constitute the gate, source, and drain of the transfer transistor, respectively. When a voltage may be applied to the transmission gate electrode 112, a channel of the second conductivity type may be formed in a region adjacent to the transmission gate electrode 112 of the first substrate 102. The channel may be configured to move charge carriers generated in the photoelectric conversion region 108 to the floating diffusion region 110. When no voltage may be applied to the transmission gate electrode 112, charge carriers generated in the photoelectric conversion region 108 may accumulate within the photoelectric conversion region 108.

In some example embodiments, the first layer 100 may include a ground region (not shown). The ground region may be provided on top of the first substrate 102. The ground region may have the second conductivity type. The ground region may be formed by injecting second impurities into the first substrate 102. The ground region may be spaced apart from the photoelectric conversion region 108. The ground region may be configured to apply a ground voltage to the first substrate 102.

The first layer 100 may include a first insulating layer 142. The first insulating layer 142 may be provided on the first front surface 102a. The first insulating layer 142 may include an electrical insulating material. For example, the first insulating layer 142 may include silicon nitride, silicon oxide, silicon oxynitride, or a combination thereof.

The first layer 100 may include first conductive lines 150. The first conductive lines 150 may be provided within the first insulating layer 142. The first conductive lines 150 may include a 1a conductive line 150a and a 1b conductive line 150b. The 1a conductive line 150a may be electrically connected to the floating diffusion region 110. The 1b conductive line 150b may be electrically connected to the transmission gate electrode 112. Each of the 1a conductive line 150a and the 1b conductive line 150b may include first vertical conductive lines 152 and first horizontal conductive lines 154. The first vertical conductive lines 152 may extend along the third direction D3. The first horizontal conductive lines 154 may be respectively disposed between the first vertical conductive lines 152 to electrically connect the first vertical conductive lines 152 that may be immediately adjacent to each other. The first horizontal conductive lines 154 may extend along a direction parallel to the first front surface 102a. For example, the first horizontal conductive line 154 may extend along the first direction D1 or the second direction D2. In some example embodiments, first vertical conductive lines 152 that may be immediately adjacent to each other but may be directly connected to different floating diffusion regions 110 may be electrically connected to each other by one first horizontal conductive line 154. The first vertical conductive lines 152 and first horizontal conductive lines 154 may include an electrically conductive material. For example, the first vertical conductive lines 152 and the first horizontal conductive lines 154 may be doped polysilicon or metal (e.g., copper (Cu), aluminum (Al), molybdenum (Mo), platinum (Pt), titanium (Ti), tantalum (Ta), tungsten (W), or a combination thereof).

The first layer 100 may include a first pad 162. The first pad 162 may be provided on the first vertical conductive lines 152 located furthest from the first front surface 100a. The first pad 162 may include copper (Cu) or a copper alloy. The first pad 162 may be configured to form a copper (Cu)—copper (Cu) bond with the second pad 262, which will be described below. As in some example embodiments, one first pad 162 may be shown. In some example embodiments, the number of first pads 162 may be determined as needed. For example, the number of first pads 162 may be the same as the number of second pads 262.

The second layer 200 may include a second substrate 202. The second substrate 202 may be provided on the first insulating layer 142. The second substrate 202 may be a semiconductor substrate. For example, the second substrate 202 may include silicon (Si), germanium (Ge), or silicon-germanium (SiGe). The second substrate 202 may include a second front surface 202a and a second back surface 202b facing opposite directions. The second front surface 202a and the second back surface 202b may extend along the first direction D1 and the second direction D2. The second front surface 202a and the second back surface 202b may be spaced apart from each other along the third direction D3. The second back surface 202b may be arranged to face the first front surface 102a. The second front surface 202a may be disposed opposite to the second back surface 202b. The second substrate 202 may have the first conductivity type.

The second layer 200 may include a second device isolation layer 204. The second device isolation layer 204 may be provided on the second substrate 202. The second device isolation layer 204 may define an active region. The active region may be a region where a pixel transistor 210, which will be described below, may be provided. In a plan view, the second device isolation layer 204 may surround the active region. The second device isolation layer 204 may have a thickness along the third direction D3. For example, the second device isolation layer 204 may be a shallow trench isolation layer (STI). In some example embodiments, the top surface of the second isolation layer 204 may be located at substantially the same level as the second front surface 202a. The second device isolation layer 204 may include silicon nitride, silicon oxide, silicon oxynitride, or a combination thereof.

The second layer 200 may include pixel transistors 210. Pixel transistors 210 may be used to drive an image sensor. Pixel transistors 210 may be provided adjacent to the second front surface 202a. The pixel transistors 210 may include first pixel transistors 210a and second pixel transistors 210b. The first pixel transistors 210a may be electrically connected to the floating diffusion region 110. For example, the first pixel transistors 210a may include a dual conversion gain transistor and a source follower transistor. The floating diffusion region 110 may be electrically connected to the drain terminal of the double conversion gain transistor and the gate terminal of the source follower transistor. The second pixel transistors 210b may be electrically connected to at least one of the first pixel transistors 210a. For example, the second pixel transistors 210b may include a reset transistor and a selection transistor. The drain terminal of the reset transistor may be electrically connected to the source terminal of the double conversion gain transistor. The input terminal of the selection transistor may be electrically connected to the source terminal (output terminal) of the source follower transistor. For brevity of explanation, a reset transistor among the second pixel transistors 210b may be shown.

The pixel transistors 210 may include a gate-all-around type transistor. Each of the first pixel transistors 210a and the second pixel transistors 210b may include a pair of pixel source/drain regions 211, a pixel gate electrode 213, a pixel gate insulating layer 214, and a pixel channel region 215, and pixel spacers 216. A pair of pixel source/drain regions 211 may be a source region and a drain region of the pixel transistor 210, respectively. A pair of pixel source/drain regions 211 may be spaced apart from each other with the pixel gate electrode 213 interposed therebetween. A pair of pixel source/drain regions 211 may be connected by a pixel channel region 215. As in some example embodiments, the pair of pixel source/drain regions 211 may be shown to be spaced apart from each other along the first direction D1. The separation direction of a pair of pixel source/drain regions 211 may be determined according to the shape of the pixel transistor 210. A pair of pixel source/drain regions 211 may be an epi layer formed through an epitaxial growth process. For example, a pair of pixel source/drain regions 211 may include silicon (Si), germanium (Ge), or silicon-germanium (SiGe). A pair of pixel source/drain regions 211 may have the second conductivity type.

The pixel gate electrode 213 may be provided between a pair of pixel source/drain regions 211. The pixel gate electrode 213 may include an electrically conductive material. For example, the pixel gate electrode 213 may be doped polysilicon or metal (e.g., copper (Cu), aluminum (Al), molybdenum (Mo), platinum (Pt), titanium (Ti), tantalum. (Ta), tungsten (W), or a combination thereof). When the pixel transistor 210 may be a source follower transistor, the pixel gate electrode 213 may be electrically connected to the floating diffusion region 110. The voltage resulting from the amount of charge accumulated in the floating diffusion region may be the gate voltage. When the pixel transistor 210 may be a reset transistor, a reset signal voltage may be applied to the pixel gate electrode 213 to apply an initial voltage to the floating diffusion region 110. Applying an initial voltage to the floating diffusion region 110 may be referred to as a reset operation. When the pixel transistor 210 may be a selection transistor, a selection signal voltage may be applied to the pixel gate electrode 213 to output a signal. A channel of the pixel transistor 210 may be formed between a pair of pixel source/drain regions 211 by the voltage applied to the pixel gate electrode 213.

The pixel channel region 215 may be provided on the second front surface 202a. The pixel channel region 215 may be spaced apart from the second front surface 202a. The pixel channel region 215 may penetrate the pixel gate electrode 213. For example, the pixel channel region 215 may extend along the first direction D1 and connect a pair of pixel source/drain regions 211. Side surfaces of the pixel channel region 215 extending along the first direction D1 may be surrounded by the pixel gate electrode 213. Accordingly, side surfaces extending along the first direction D1 of the pixel channel region 215 may be used as a channel for the pixel transistor 210. As in some example embodiments, three pixel channel regions 215 may be shown. In some example embodiments, fewer or more than three pixel channel regions 215 may be provided. The pixel channel region 215 may be an epi layer formed through an epitaxial growth process. For example, the pixel channel regions 215 may include silicon (Si), germanium (Ge), or silicon-germanium (SiGe). The pixel channel regions 215 may have a first conductivity type.

The pixel gate insulating layer 214 may be provided between the pixel gate electrode 213 and the pixel channel regions 215. The pixel gate insulating layer 214 may include an electrical insulating material. For example, the pixel gate insulating layer 214 may include silicon oxide, silicon nitride, or silicon oxynitride. The pixel gate insulating layer 214 may be configured to electrically separate the pixel gate electrode 213 and the pixel channel regions 215.

Pixel spacers 216 may be disposed between the first pixel source/drain region 211 and the pixel gate electrode 213 and between the second pixel source/drain region 211 and the pixel gate electrode 213, respectively. Pixel spacers 216 may include electrically insulating material. For example, pixel spacers 216 may be made of an insulating material (e.g., a silicon-based insulating material (e.g., silicon nitride, silicon oxide, and/or silicon oxynitride) or a high dielectric material (e.g., a metal oxide containing at least one metal selected from the group consisting of hafnium (Hf), zirconium (Zr), aluminum (Al), tantalum (Ta), titanium (Ti), yttrium (Y), and lanthanoid (La)). The pixel spacers 216 may be configured to electrically separate a pair of pixel source/drain regions 211 from the pixel gate electrode 213.

The second layer 200 may include a second insulating layer 222. The second insulating layer 222 may be provided on the second back surface 202b. The second insulating layer 222 may include an electrical insulating material. For example, the second insulating layer 222 may include silicon nitride, silicon oxide, silicon oxynitride, or a combination thereof.

The second layer 200 may include a second pad 262. The second pad 262 may be in direct contact with the first pad 162. The second pad 262 may include copper (Cu) or a copper alloy. The second pad 262 may be configured to form a copper (Cu)—copper (Cu) bond with the first pad 162. As in some example embodiments, one second pad 262 may be shown. The number of second pads 262 may be determined as needed. For example, the number of second pads 262 may be the same as the number of first pads 162.

The second layer 200 may include a second conductive line 230. The second conductive line 230 may be provided within the second insulating layer 222. The second conductive line 230 may be electrically connected to the second pad 262 and the first pixel transistors 210a. The second conductive lines 230 may include a second vertical conductive line 232 and a second horizontal conductive line 234.

The second vertical conductive lines 232 may be configured to penetrate the second insulating layer 222. The second vertical conductive lines 232 may extend along the third direction D3. The second vertical conductive line 232 immediately adjacent to the second pad 262 may be configured to directly contact the second pad 262. The second vertical conductive line 232 immediately adjacent to the first pixel transistor 210a may pass through the second substrate 202 and be electrically connected to the first pixel transistor 210a. For example, the second vertical conductive line 232 immediately adjacent to the first pixel transistor 210a may pass through the second substrate 202 and be connected to the bottom of the first pixel transistor 210a. The lower part of the first pixel transistor 210a may refer to a portion of the first pixel transistor 210a adjacent to the second front surface 202a. The second vertical conductive line 232 immediately adjacent to the first pixel transistor 210a may overlap the first pixel transistor 210a in the third direction D3. The second vertical conductive line 232 immediately adjacent to the first pixel transistor 210a may be spaced apart from the third insulating layer 242, which will be described below. The second vertical conductive lines 232 may include an electrically conductive material. For example, the second vertical conductive lines 232 may be doped polysilicon or metal (e.g., copper (Cu), aluminum (Al), molybdenum (Mo), platinum (Pt), titanium (Ti)), tantalum (Ta), tungsten (W), or a combination thereof).

The second vertical conductive line 232 immediately adjacent to the source follower transistor of the first pixel transistor 210a may overlap the pixel gate electrode 213 of the source follower transistor along the third direction D3. The second vertical conductive line 232 immediately adjacent to the source follower transistor may directly contact the back surface of the pixel gate electrode 213 of the source follower transistor. The back surface of the pixel gate electrode 213 of the source follower transistor may be a surface of the pixel gate electrode 213 immediately adjacent to the second front surface 202a.

The second vertical conductive line 232 immediately adjacent to the double conversion gain transistor of the first pixel transistor 210a may be overlapped to one of the pair of pixel source/drain regions 211 of the double conversion gain transistor in the third direction D3. One of the pair of pixel source/drain regions 211 may be the drain of a dual conversion gain transistor. The second vertical conductive line 232 immediately adjacent to the dual conversion gain transistor may directly contact the back surface of one of the pair of pixel source/drain regions 211 of the dual conversion gain transistor. The back surface of one of the pair of pixel source/drain regions 211 of the dual conversion gain transistor may be the surface of one of the pair of pixel source/drain regions 211 immediately adjacent to the second front surface 202a.

The second horizontal conductive line 234 may be provided between the second vertical conductive lines 232. The second horizontal conductive line 234 may electrically connect the second vertical conductive lines 232 that may be immediately adjacent to each other. As in some example embodiments, one second horizontal conductive line 234 may be shown. The number of second horizontal conductive lines 234 may be determined as needed. The second horizontal conductive line 234 may extend along a direction parallel to the second back surface 202b. For example, the second horizontal conductive line 234 may extend along the first direction D1 or the second direction D2. The second horizontal conductive line 234 may include an electrically conductive material. For example, the second horizontal conductive line 234 may be doped polysilicon or metal (e.g., copper (Cu), aluminum (Al), molybdenum (Mo), platinum (Pt), titanium (Ti), tantalum (Ta), tungsten (W), or a combination thereof).

The second layer 200 may include a third insulating layer 242. A third insulating layer 242 may be provided on the second front surface 202a. The third insulating layer 242 may include an electrical insulating material. For example, the third insulating layer 242 may include silicon nitride, silicon oxide, silicon oxynitride, or a combination thereof.

The second layer 200 may include a third conductive line 250. The third conductive line 250 may be provided within the third insulating layer 242. The third conductive line 250 may be electrically connected to the first pixel transistors 210a and the second pixel transistors 210b. In some example embodiments, the third conductive lines 250 may be electrically connected to the second pad 262 disposed in the pad region PDA. The third conductive lines 250 may include a third vertical conductive line 252 and a third horizontal conductive line 254.

The third vertical conductive lines 252 may be configured to penetrate the third insulating layer 242. The third vertical conductive lines 252 may extend along the third direction D3. The third vertical conductive lines 252 may include an electrically conductive material. For example, the third vertical conductive lines 252 may be doped polysilicon or metal (e.g., copper (Cu), aluminum (Al), molybdenum (Mo), platinum (Pt), titanium (Ti), tantalum (Ta), tungsten (W), or a combination thereof).

Third horizontal conductive lines 254 may be provided between the third vertical conductive lines 252. The third horizontal conductive line 254 may electrically connect third vertical conductive lines 252 that may be immediately adjacent to each other. The third horizontal conductive line 254 may extend along a direction parallel to the second back surface 202b. For example, the third horizontal conductive line 254 may extend along the first direction D1 or the second direction D2. The third horizontal conductive line 254 may include an electrically conductive material. For example, the third horizontal conductive line 254 may be doped polysilicon or metal (e.g., copper (Cu), aluminum (Al), molybdenum (Mo), platinum (Pt), titanium (Ti), tantalum (Ta), tungsten (W), or a combination thereof).

A color filter 132 and a micro lens 134 may be provided on the first back surface 102b of the first substrate 102. Color filters 132 may be provided at positions corresponding to the photoelectric conversion regions 108, respectively. Each of the color filters 132 may include one of a red filter, a blue filter, and a green filter, but the inventive concepts may be not limited thereto, and filters of other colors may be provided. Color filters 132 may form color filter arrays. For example, the color filters 132 may form an array arranged along the first direction D1 and the second direction D2 when viewed on a plane.

The micro lens 134 may be disposed on the color filter 132. The micro lens 134 may include a lens pattern and a flattening portion. The flattening portion of the micro lens 134 may be provided on the color filters 132. The lens pattern may be provided on the planarized portion. The lens pattern may be formed integrally with the flattening portion and may be connected without an interface. The lens pattern may include the same material as the planarization portion. As another example, the flattening portion may be omitted, and the lens pattern may be placed directly on the color filters 132. The lens pattern may be hemispherical. The lens pattern may converge incident light. Lens patterns may be provided at positions corresponding to the photoelectric conversion regions 108. The micro lens 134 may be transparent and may transmit light. The micro lens 134 may include an organic material such as a polymer. For example, the micro lens 134 may include a photoresist material or a thermosetting resin. Although not shown, a protective layer may be provided on the micro lens 134, and the protective layer may include an organic material and/or an inorganic material. According to some example embodiments, the protective layer may include a silicon-containing material such as silicon oxide, silicon nitride, silicon oxynitride, silicon carbide, silicon carbide oxide, silicon carbonitride, and/or silicon carboxynitride. As another example, the protective layer may include aluminum oxide, zinc oxide, and/or hafnium oxide. The protective layer may have insulating properties, but may be not limited thereto. The protective layer may transmit light.

In the present disclosure, the second conductive line 230 may be configured to directly contact the back surface of the pixel gate electrode 213 of the first pixel transistor 210a or one of the pair of pixel source/drain regions 211. Unlike the present disclosure, when the second conductive line 230 directly contacts the front surface of the pixel gate electrode 213 of the first pixel transistor 210a or the pair of pixel source/drain regions 211, the second conductive line 230 may be configured to pass through the second insulating layer 222, the second substrate 202, and the third insulating layer 242. In order for the second conductive line 230 to extend through the second substrate 202 to the third insulating layer 242, a region of the second substrate 202 that may be horizontally spaced from the first pixel transistor 210a should be used for the second conductive line 230. In the present disclosure, the second conductive line 230 penetrates the second substrate 202 and may be directly connected to the pixel gate electrode 213 of the first pixel transistor 210a or a pair of pixel source/drain regions 211. Therefore, from a plan view, one region of the second substrate 202 for arranging the second conductive line 230 may be not required. Accordingly, a miniaturized image sensor 10 may be provided.

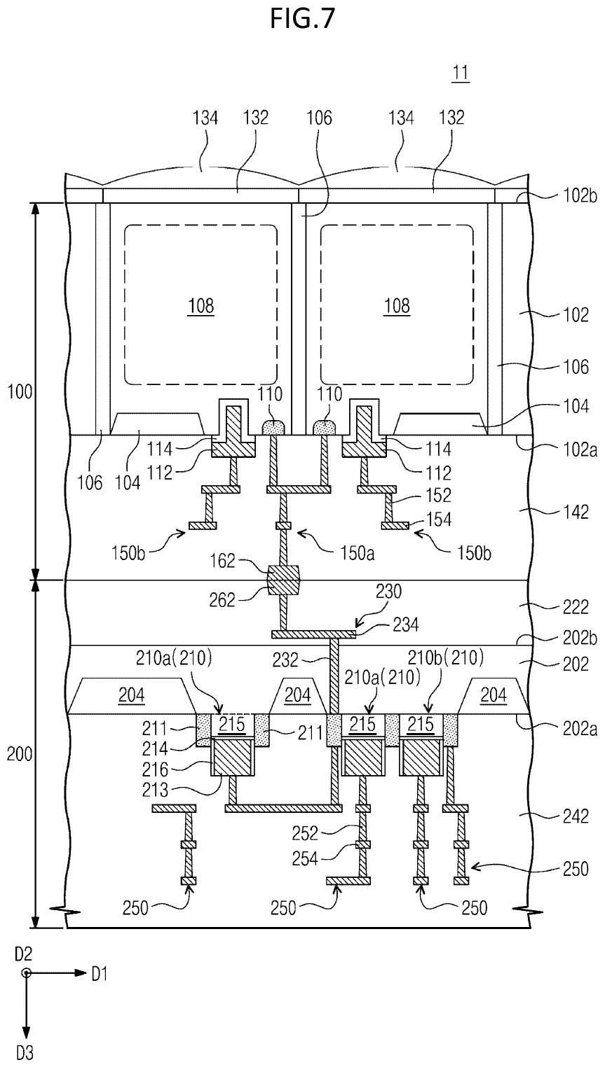

FIG. 7 is a cross-sectional view of an image sensor according to some example embodiments. For brevity of explanation, differences from those described with reference to FIGS. 5 and 6 may be mainly explained.

Referring to FIG. 7, a first layer 100 and a second layer 200 arranged along the third direction D3 may be provided. Unlike what may be described with reference to FIGS. 5 and 6, the pixel transistors 210 may be of the FINFET type. The pixel transistors 210 may include a pair of pixel source/drain regions 211, a pixel gate electrode 213, a pixel gate insulating layer 214, pixel channel regions 215, and pixel spacers 216.

The pixel channel region 215 may be connected to the second substrate 202. The pixel channel region 215 may protrude from the second front surface 202a. The pixel channel region 215 may be connected to the second substrate 202. For example, the back surface of the pixel channel region 215 may contact the second front surface 202a. The back surface of the pixel channel region 215 may be facing the second front surface 202a. The pixel channel region 215 may connect a pair of pixel source/drain regions 211. The pixel channel region 215 may extend along the first direction D1. Side surfaces (not shown) extending along the first direction D1 of the pixel channel region 215 may be covered by the pixel gate electrode 213. Accordingly, side surfaces of the pixel channel regions 215 extending along the first direction D1 may be used as a channel for the pixel transistor 210.

Unlike what may be explained with reference to FIGS. 5 and 6, the pixel gate electrode 213 of the source follower transistor and one of the pair of pixel source/drain regions 211 of the dual conversion gain transistor may be electrically connected to each other by the third conductive line 250 instead of the second conductive line 230. For example, the second conductive line 230 may be provided between the second pad 262 and one of the pair of pixel source/drain regions 211 of the dual conversion gain transistor. For example, the third conductive line 250 may be provided between the pixel gate electrode 213 of the source follower transistor and one of the pair of pixel source/drain regions 211 of the dual conversion gain transistor. The third vertical conductive line 252 immediately adjacent to the dual conversion gain transistor may directly contact the front surface of one of the pair of pixel source/drain regions 211 of the dual conversion gain transistor. The front surface of one of the pair of pixel source/drain regions 211 of the dual conversion gain transistor may be the surface of one of the pair of pixel source/drain regions 211 immediately adjacent to the second front surface 202a.

In the present disclosure, since the second conductive line 230 passes through the second substrate 202 and may be directly connected to one of the pair of pixel source/drain regions 211 of the first pixel transistor 210a, the second conductive line 230 may be connected to the first pixel transistor 210a. One region of the second substrate 202 to place the conductive line 230 may be not required. Accordingly, a miniaturized image sensor 11 may be provided.

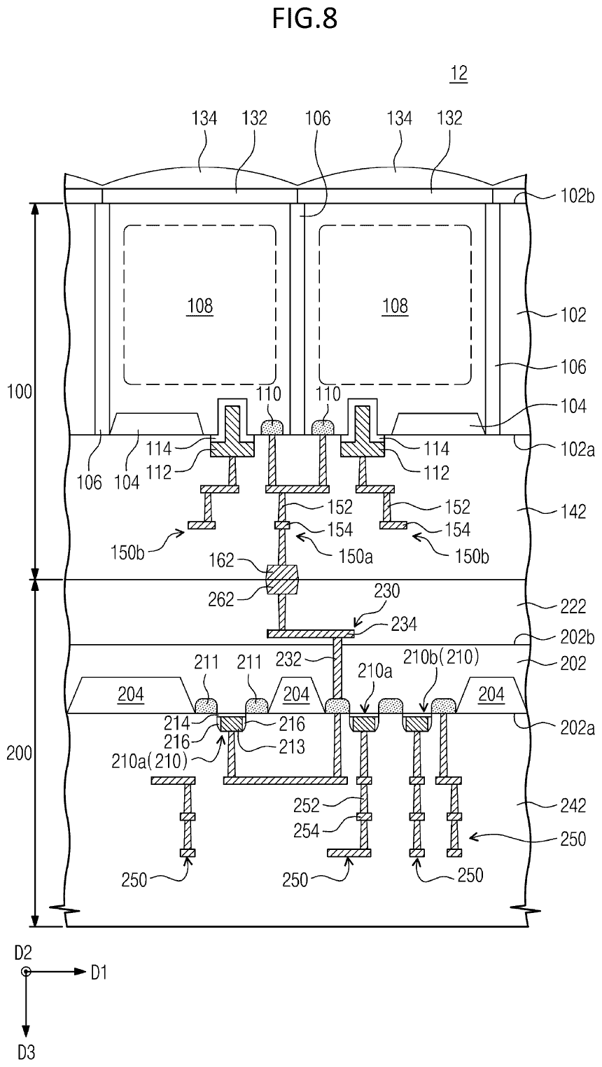

FIG. 8 is a cross-sectional view of an image sensor according to some example embodiments. For brevity of explanation, differences from those described with reference to FIGS. 5 and 6 may be mainly explained.

Referring to FIG. 8, a first layer 100 and a second layer 200 arranged along the third direction D3 may be provided. Unlike what may be described with reference to FIGS. 5 and 6, the pixel transistors 210 may include planar type transistors. A pair of pixel source/drain regions 211 may be provided on the second substrate 202. A pixel channel region may be provided on the second substrate 202 between a pair of pixel source/drain regions 211. The pixel gate electrode 213 may be provided on the second front surface 202a of the second substrate 202. The pixel gate insulating layer 214 may be provided between the pixel gate electrode 213 and the second front surface 202a. From a perspective along the third direction D3, a pair of pixel source/drain regions 211 may be spaced apart from each other with the pixel gate electrode 213 interposed therebetween. As in some example embodiments the pair of pixel source/drain regions 211 may be shown to be spaced apart from each other along the first direction D1. The separation direction of a pair of pixel source/drain regions 211 may be determined according to the shape of the pixel transistor 210. A pair of pixel source/drain regions 211 may have a second conductivity type.

The pixel gate electrode 213 of the source follower transistor and one of the pair of pixel source/drain regions 211 of the dual conversion gain transistor may be electrically connected to each other by the third conductive line 250 instead of the second conductive line 230. For example, a second conductive line 230 may be provided between the second pad 262 and one of the pair of pixel source/drain regions 211 of the dual conversion gain transistor. For example, a third conductive line 250 may be provided between the pixel gate electrode 213 of the source follower transistor and one of the pair of pixel source/drain regions 211 of the dual conversion gain transistor. The third vertical conductive line 252 immediately adjacent to the dual conversion gain transistor may directly contact the front surface of one of the pair of pixel source/drain regions 211 of the dual conversion gain transistor. The front surface of one of the pair of pixel source/drain regions 211 of the dual conversion gain transistor may be the surface of one of the pair of pixel source/drain regions 211 immediately adjacent to the second front surface 202a.

In the present disclosure, since the second conductive line 230 passes through the second substrate 202 and is directly connected to one of the pair of pixel source/drain regions 211 of the first pixel transistor 210a, from a plan view, one region of the second substrate 202 for disposing the second conductive line 230 may be not required. Accordingly, a miniaturized image sensor 12 may be provided.

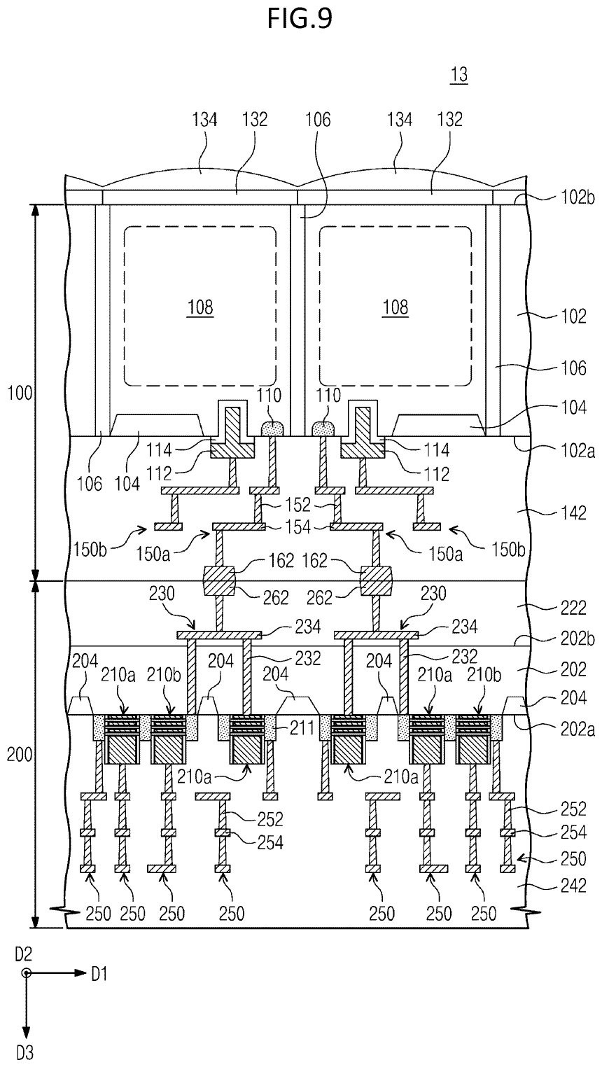

FIG. 9 is a cross-sectional view of an image sensor according to some example embodiments. For brevity of explanation, differences from those described with reference to FIGS. 5 and 6 may be mainly explained.

Referring to FIG. 9, a first layer 100 and a second layer 200 arranged along the third direction D3 may be provided. Unlike what may be described with reference to FIGS. 5 and 6, the first vertical conductive lines 152 that may be directly adjacent to each other and may be directly connected to different floating diffusion regions 110 may be connected to the first horizontal conductive lines 154, respectively. The plurality of pixels PXL may be configured not to share the pixel transistor 210. For example, each of the plurality of pixels PXL may include a dual conversion gain transistor, a source follower transistor, a reset transistor, and a selection transistor.

In the present disclosure, since the second conductive line 230 passes through the second substrate 202 and may be directly connected to one of the pair of pixel source/drain regions 211 of the first pixel transistor 210a, from a plan view one region of the second substrate 202 for disposing the second conductive line 230 may be not required. Accordingly, a miniaturized image sensor 13 may be provided.

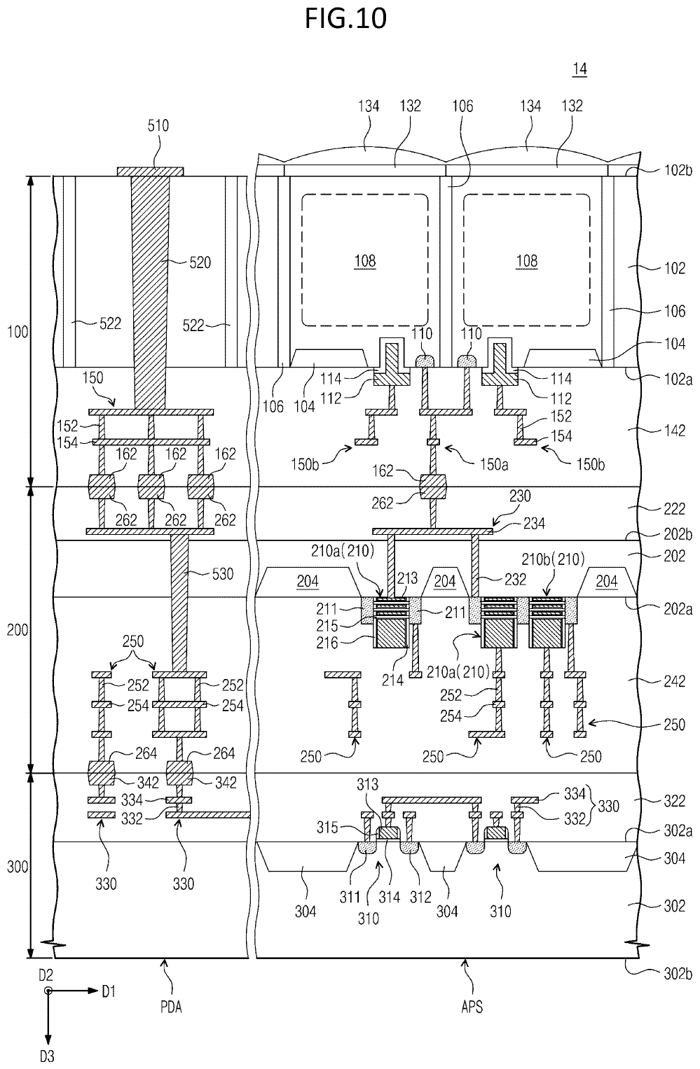

FIG. 10 is a cross-sectional view of an image sensor according to some example embodiments. For brevity of explanation, differences from those described with reference to FIGS. 5 and 6 may be mainly explained.

Referring to FIG. 10, an image sensor 14 may be provided including a pixel array region APS and a pad region PDA. The image sensor 14 may be provided with a first layer 100, a second layer 200, and a third layer 300 arranged along the third direction D3. The first layer 100 and the second layer 200 of the pixel array region APS may be substantially the same as the first layer 100 and the second layer 200 described with reference to FIGS. 5 and 6.

The third layer 300 of the pixel array region APS may include a third substrate 302. The third substrate 302 may be provided on the third insulating layer 242. The third substrate 302 may be a semiconductor substrate. For example, the third substrate 302 may include silicon (Si), germanium (Ge), or silicon-germanium (SiGe). The third substrate 302 may include a third front surface 302a and a third back surface 302b facing opposite directions. The third front surface 302a may be configured to face the second front surface 202a. The third front surface 302a and the third back surface 302b may extend along the first direction D1 and the second direction D2. The third front surface 302a and the third back surface 302b may be spaced apart from each other along the third direction D3. The third substrate 302 may have a first conductivity type. For example, the first conductivity type may be p-type or n-type. When the conductivity type of the third substrate 302 may be p-type, the third substrate 302 may be a silicon (Si) substrate containing Group 3 elements (e.g., boron (B), aluminum (Al), gallium (Ga), indium (In), etc.) or Group 2 elements as impurities. When the conductivity type of the third substrate 302 may be n-type, the third substrate 302 may be a silicon (Si) substrate containing Group 5 elements (e.g., phosphorus (P), arsenic (As), antimony (Sb), etc.), Group 6, or Group 7 elements as impurities.

Logic transistors 310 may be provided on the third substrate 302. The logic transistors 310 may include a first logic source/drain region 311, a second logic source/drain region 312, a logic gate electrode 313, a logic gate insulating layer 314, and logic spacers 315. The first logic source/drain region 311 and the second logic source/drain region 312 may be provided on the third substrate 302. From a plan view, the first logic source/drain region 311 and the second logic source/drain region 312 may be spaced apart from each other with the logic gate electrode 313 therebetween. A logic channel region may be provided on the third substrate 302 between the first logic source/drain region 311 and the second logic source/drain region 312. As in some example embodiments, the first logic source/drain region 311 and the second logic source/drain region 312 may be shown to be spaced apart from each other along the first direction D1. The separation direction of the first logic source/drain region 311 and the second logic source/drain region 312 may be determined according to the shape of the logic transistor 310. The first logic source/drain region 311 and the second logic source/drain region 312 may have a second conductivity type. One of the first logic source/drain region 311 and the second logic source/drain region 312 may be a source region, and the other may be a drain region.

The logic gate electrode 313 may be provided between the first logic source/drain region 311 and the second logic source/drain region 312. The logic gate electrode 313 may be provided on the third substrate 302. The logic gate electrode 313 may include an electrically conductive material. For example, the logic gate electrode 313 may be doped polysilicon or metal (e.g., copper (Cu), aluminum (Al), molybdenum (Mo), platinum (Pt), titanium (Ti), tantalum. (Ta), tungsten (W), or a combination thereof).

The logic gate insulating layer 314 may be provided between the logic gate electrode 313 and the third front surface 302a. The logic gate insulating layer 314 may include an electrical insulating material. For example, the logic gate insulating layer 314 may include silicon oxide, silicon nitride, or silicon oxynitride. The logic gate insulating layer 314 may be configured to electrically separate the logic gate electrode 313 and the third substrate 303.

Logic spacers 315 may be disposed between the first logic source/drain region 311 and the logic gate electrode 313 and between the second logic source/drain region 312 and the logic gate electrode 313, respectively. The logic spacers 315 may include electrical insulating material. For example, the logic spacers 315 may be made of an insulating material (e.g., a silicon-based insulating material (e.g., silicon nitride, silicon oxide, and/or silicon oxynitride) or a high-k dielectric material (e.g., a metal oxide containing at least one metal selected from the group consisting of hafnium (Hf), zirconium (Zr), aluminum (Al), tantalum (Ta), titanium (Ti), yttrium (Y), and lanthanoid (La)). The logic spacers 315 may be configured to electrically separate the first logic source/drain region 311 and the second logic source/drain region 312 from the logic gate electrode 313.

The third layer 300 may include a fourth insulating layer 322. The fourth insulating layer 322 may be provided on the third front surface 302a. The fourth insulating layer 322 may be provided between the third insulating layer 242 and the third substrate 302. The fourth insulating layer 322 may include an electrical insulating material. For example, the fourth insulating layer 322 may include silicon nitride, silicon oxide, silicon oxynitride, or a combination thereof.

The third layer 300 may include fourth conductive lines 330. Fourth conductive lines 330 may be provided within the fourth insulating layer 322. The fourth conductive lines 330 may be electrically connected to the logic transistors 310. In some example embodiments, the fourth conductive lines 330 may be electrically connected to the first logic source/drain region 311, the second logic source/drain region 312, and the logic gate electrode 313 of the logic transistors 310.

The fourth conductive lines 330 may be electrically connected to the second pad 262 disposed in the pad region PDA. The fourth conductive lines 330 may include a third vertical conductive line 332 and a third horizontal conductive line 334.

The third vertical conductive lines 332 may be configured to penetrate the fourth insulating layer 322. The third vertical conductive lines 332 may extend along the third direction D3. The third vertical conductive lines 332 may include an electrically conductive material. For example, the third vertical conductive lines 332 may be doped polysilicon or metal (e.g., copper (Cu), aluminum (Al), molybdenum (Mo), platinum (Pt), titanium (Ti), tantalum (Ta), tungsten (W), or a combination thereof).

Third horizontal conductive lines 334 may be provided between the third vertical conductive lines 332. The third horizontal conductive line 334 may electrically connect third vertical conductive lines 332 that may be immediately adjacent to each other. The third horizontal conductive line 334 may extend along a direction parallel to the second back surface 202b. For example, the third horizontal conductive line 334 may extend along the first direction D1 or the second direction D2. The third horizontal conductive line 334 may include an electrically conductive material. For example, the third horizontal conductive line 334 may be doped polysilicon or metal (e.g., copper (Cu), aluminum (Al), molybdenum (Mo), platinum (Pt), titanium (Ti), tantalum (Ta), tungsten (W), or a combination thereof).

A first substrate 102, a first insulating layer 142, a second insulating layer 222, a second substrate 202, a third insulating layer 242, a fourth insulating layer 322, and a third substrate 302 may extend into the pad region PDA. A main via 520 may be provided in the pad region PDA. The main via 520 may extend along the third direction D3. The main via 520 may be configured to penetrate the first substrate 102. One end of the main via 520 may be exposed on the first back surface 102b. One end of the main via 520 may directly contact the signal pad 510. The other end of the main via 520 may be inserted into the first insulating layer 142. The main via 520 may be configured to have low resistance. For example, the main via 520 may have a larger cross-sectional region than the first to fourth vertical conductive lines 332.

First conductive lines 150, first pads 162, second pads 262, second conductive lines 230, third conductive lines 250, third pads 264, fourth pads 342, and fourth conductive lines 330 may be further provided in the pad region PDA. The first pads 162 and the second pads 262 may be disposed adjacent to the joint surface of the first insulating layer 142 and the second insulating layer 222, respectively. The first pads 162 and the second pads 262 may be configured to contact each other to form copper (Cu)—copper (Cu) bonding.

The first conductive lines 150 may be provided between the first pads 162 and the main via 520 to electrically connect the first pads 162 and the main via 520. In some example embodiments, when viewed along the third direction D3, the first conductive lines 150 may have a grid shape. For example, the first horizontal conductive lines 154 may be connected to each other to form a grid. Depending on process conditions, the width of the first conductive lines 150 may be smaller than that of the main via 520. As the first conductive lines 150 may be configured in a grid shape, resistance to an electrical signal transmitted along the first conductive lines 150 may be reduced.

The second conductive lines 230 may be electrically connected to the second pads 262. In some example embodiments, the second vertical conductive lines 232 immediately adjacent to the second pads 262 may be electrically connected to one second horizontal conductive line 234.

The third pads 264 and fourth pads 342 may be disposed adjacent to joint surfaces of the third insulating layer 242 and the fourth insulating layer 322, respectively. The third pads 264 and the fourth pads 342 may be configured to contact each other to form copper (Cu)—copper (Cu) bonding. The third conductive lines 250 may be electrically connected to the third pads 264.

A middle via 530 may be provided between the second conductive lines 230 and the third conductive lines 250. The middle via 530 may be configured to electrically connect the second conductive lines 230 and the third conductive lines 250 to each other. For example, one end of the middle via 530 directly contacts the second horizontal conductive line 234 immediately adjacent the second back surface 202b, and the other end directly contacts the third horizontal conductive line 254 immediately adjacent the second front surface 202a.

Fourth conductive lines 330 may be provided between the fourth pads 342 and the logic transistors 310. The fourth conductive lines 330 may be configured to electrically connect the fourth pads 342 and the logic transistors 310.

The present disclosure may provide a miniaturized image sensor 14.

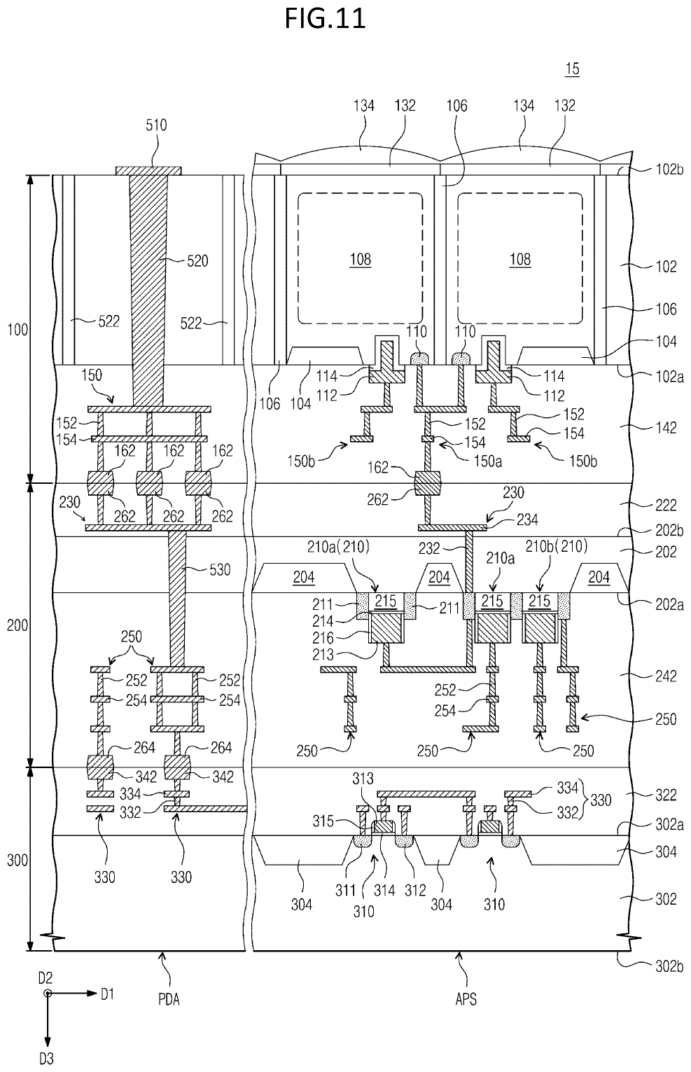

FIG. 11 is a cross-sectional view of an image sensor according to some example embodiments. For brevity of explanation, the differences between what may be described with reference to FIG. 10 and what may be described with reference to FIG. 7 may be mainly explained.

Referring to FIG. 11, an image sensor 15 may be provided including a pixel array region APS and a pad region PDA. Unlike what may be described with reference to FIG. 10, the first layer 100 and the second layer 200 of the pixel array region APS may be substantially the same as the first layer 100 and the second layer 200 described with reference to FIG. 7. For example, unlike those described with reference to FIGS. 5 and 6, the pixel transistors 210 may be of the FINFET type.

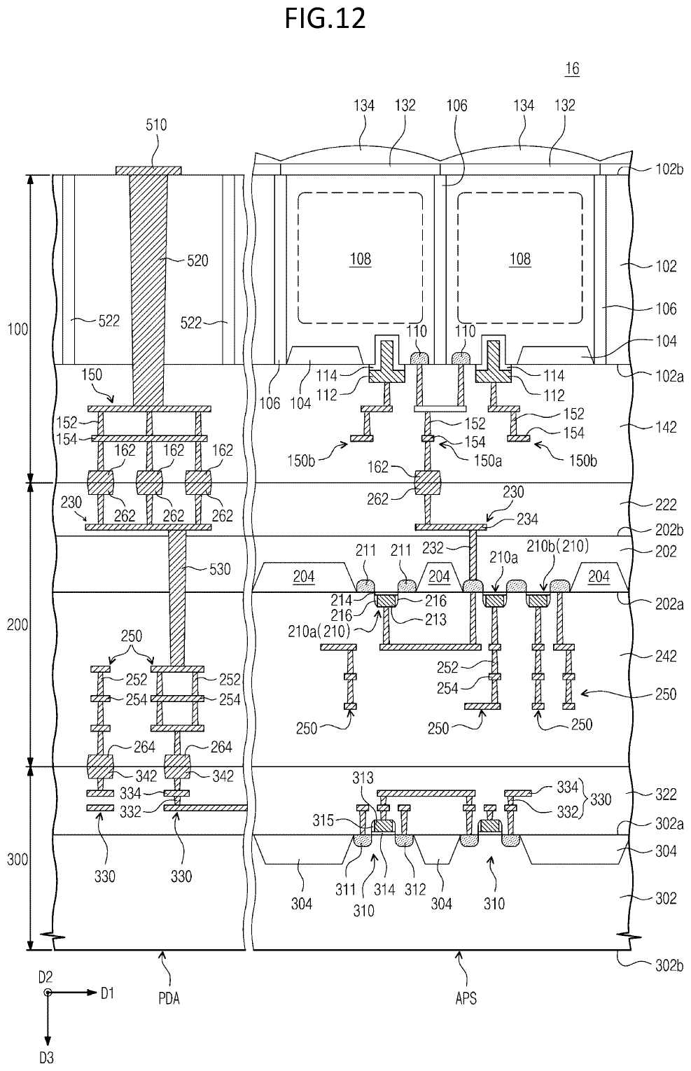

FIG. 12 is a cross-sectional view of an image sensor according to some example embodiments. For brevity of explanation, the differences between what may be described with reference to FIG. 10 and what may be described with reference to FIG. 8 may be mainly explained.

Referring to FIG. 12, an image sensor 16 may be provided including a pixel array region APS and a pad region PDA. Unlike what may be described with reference to FIG. 10, the first layer 100 and the second layer 200 of the pixel array region APS may be substantially the same as the first layer 100 and the second layer 200 described with reference to FIG. 8. For example, unlike what may be described with reference to FIGS. 5 and 6, the pixel transistors 210 may include planar type transistors.

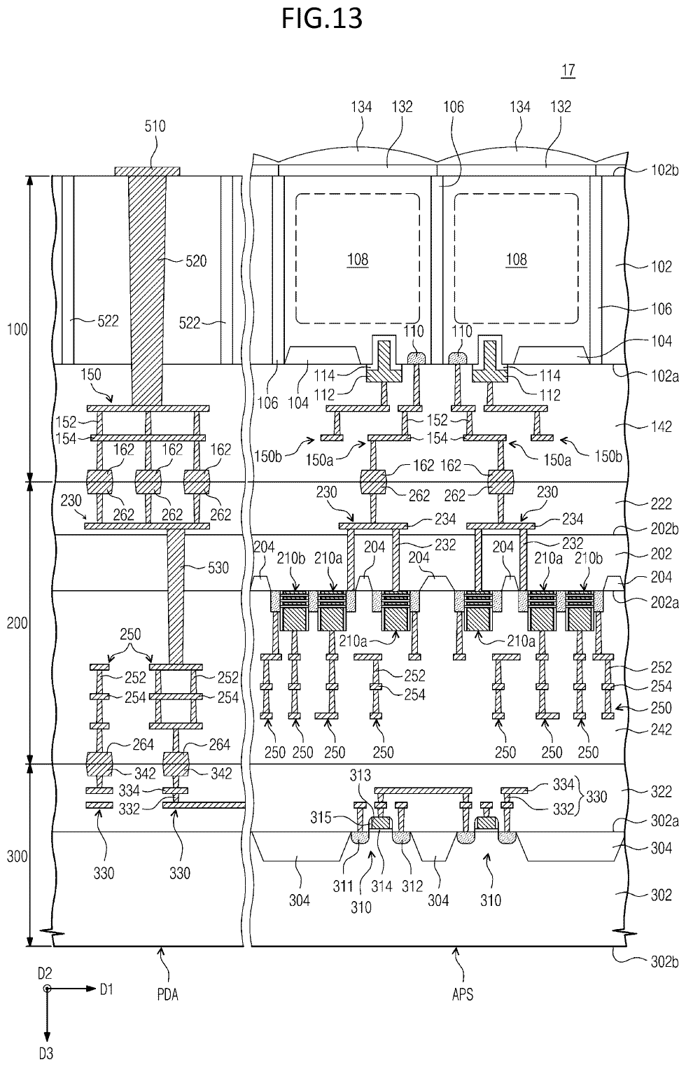

FIG. 13 is a cross-sectional view of an image sensor according to some example embodiments. For brevity of explanation, the differences between what may be described with reference to FIG. 10 and what may be described with reference to FIG. 9 may be mainly explained.

Referring to FIG. 13, an image sensor 17 may be provided including a pixel array region APS and a pad region PDA. Unlike what may be described with reference to FIG. 10, the first layer 100 and the second layer 200 of the pixel array region APS may be substantially the same as the first layer 100 and the second layer 200 described with reference to FIG. 9. For example, unlike what may be described with reference to FIGS. 5 and 6, the first vertical conductive lines 152 that may be directly adjacent to each other but may be directly connected to different floating diffusion regions 110 may be first horizontal conductive lines. Each may be connected to 154.

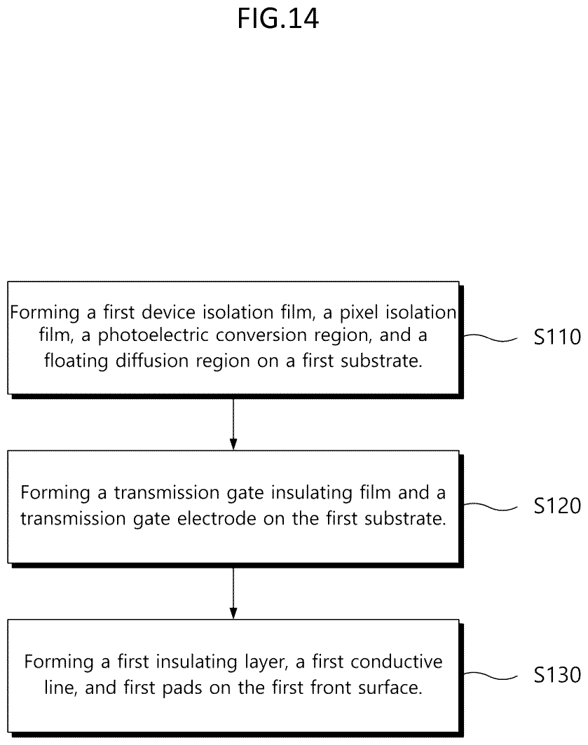

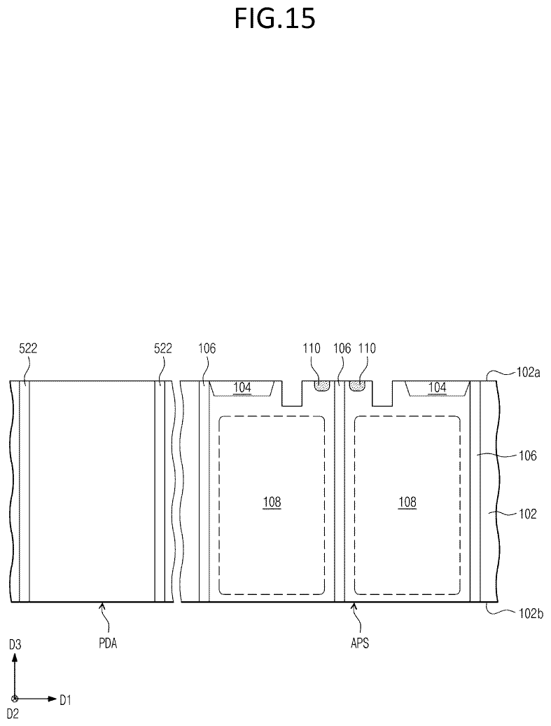

FIG. 14 is a flowchart for explaining the manufacturing method of the first layer of FIG. 10. FIGS. 15 to 17 are drawings for explaining the manufacturing method of FIG. 14. For brevity of explanation, content substantially the same as that described with reference to FIG. 10 may not be described.

Referring to FIGS. 14 and 15, a first substrate 102 may be provided. The first substrate 102 may include a pixel array region APS and a pad region PDA. The first substrate 102 may have a first conductivity type. A first device isolation layer 104, a pixel isolation layer 106, a photoelectric conversion region 108, and a floating diffusion region 110 may be formed on the first substrate 102 in the pixel array region APS (S110). The first device isolation layer 104 may be configured to define an active region. For example, the first device isolation layer 104 may be formed by etching a region of the first substrate 102 adjacent to the first front surface 102a and then filling the etched region with an insulating material.

The pixel isolation layer 106 may be formed between pixels to electrically and optically separate the pixels. For example, the pixel isolation layer 106 may be formed by etching the first substrate 102 to a required depth and then filling the etched region with a conductive material, an insulating material, or a high dielectric material. In some example embodiments, the sidewall of the pixel isolation layer 106 may be doped with a highly reflective material (e.g., boron). When the pixel separator 106 may include a conductive material, a negative fixed charge layer may be formed between the pixel separator 106 and the first substrate 102. In some example embodiments, when forming the pixel isolation layer 106, a main via isolation layer 522 may be formed that defines a region where the main via 520 may be formed.

The photoelectric conversion region 108 may include, for example, a pn photodiode. In some example embodiments, a pn photodiode may be formed in a photoelectric conversion region by injecting a second impurity (i.e., an impurity that causes the first substrate 102 to have a second conductivity type) into the first substrate 102 of the first conductivity type. In some example embodiments, first impurities (that is, impurities that cause the first substrate 102 to have a first conductivity type) may be further implanted into the first substrate 102.

The floating diffusion region 110 may be formed in a region adjacent to the first front surface 102a. The floating diffusion region 110 may be formed by injecting second impurities into the first substrate 102.

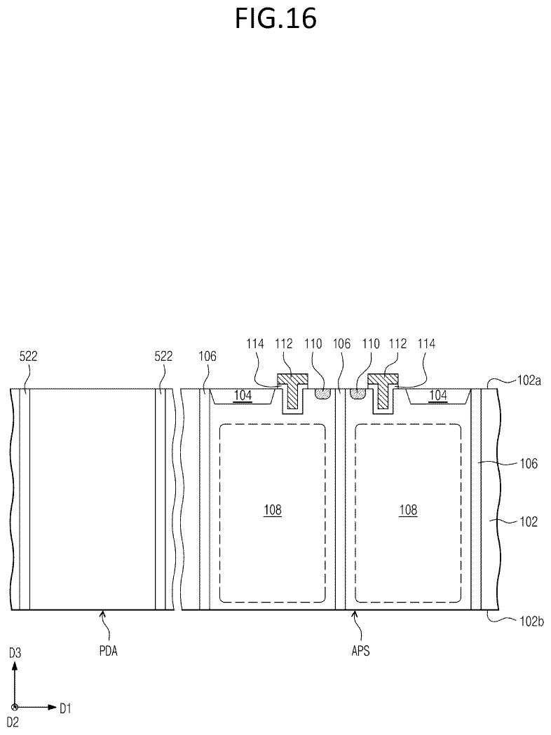

Referring to FIGS. 14 and 16, a transmission gate insulating layer 114 and a transmission gate electrode 112 may be formed on the first substrate 102 in the pixel array region APS. (S120) For example, the transmission gate insulating layer 114 and the transfer gate electrode 112 may be formed by etching a region of the first substrate 102 adjacent to the first front surface 102a, sequentially depositing an insulating layer and an electrically conductive material layer on the surface of the etched region, and patterning the insulating layer and an electrically conductive material layer.

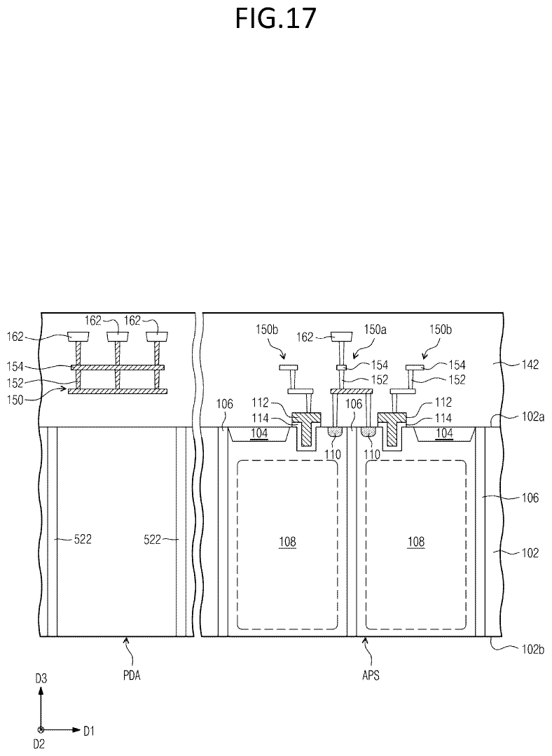

Referring to FIGS. 14 and 17, a first insulating layer 142, first conductive lines 150, and first pads 162 may be formed on the first front surface 102a (S130). For example, it may be repeated to form a portion of the first insulating layer 142 on the first front 102a, forming a portion of the first vertical conductive line 152 penetrating a portion of the first insulating layer 142 and the first horizontal conductive line 154 extending in the first direction D1 or the second direction D2 on a portion of the first insulating layer 142, forming another part of the first insulating layer 142 to cover the first horizontal conductive lines 154. The first pad 162 may be formed on the first vertical conductive lines 152 located furthest from the first front surface 102a. Some of the first conductive lines 150 may be electrically connected to the transmission gate electrodes 112. Other portions of the first conductive lines 150 may be electrically connected to the floating diffusion region 110. Another part of the first conductive lines 150 may be electrically connected to the main via 520, which will be described below.

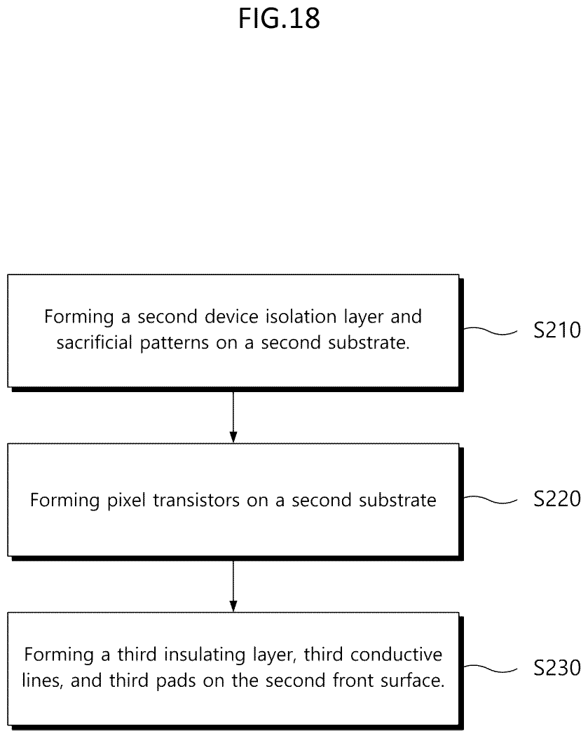

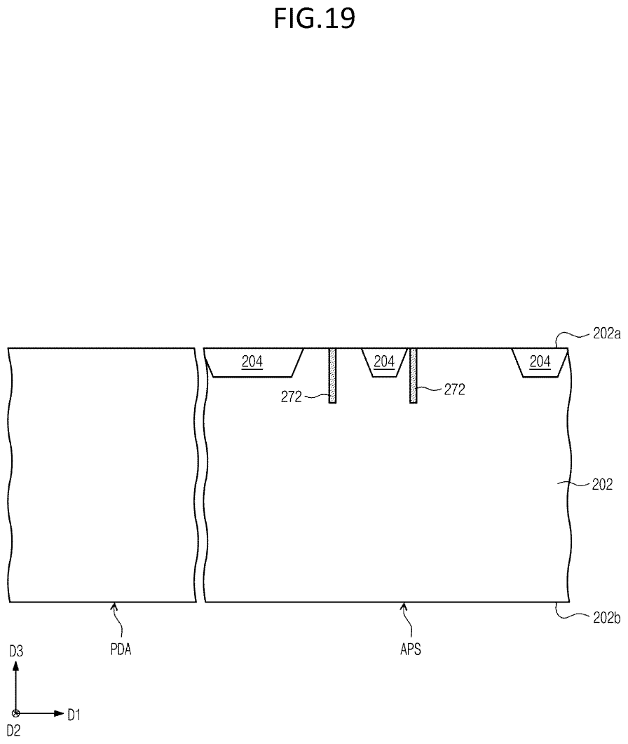

FIG. 18 is a flowchart for explaining the manufacturing method of the second layer of FIG. 10. FIGS. 19 to 21 are drawings for explaining the manufacturing method of FIG. 18. For brevity of explanation, content substantially the same as that described with reference to FIG. 10 may not be described.

Referring to FIGS. 18 and 19, a second substrate 202 may be provided. The second substrate 202 may include a pixel array region APS and a pad region PDA. The second substrate 202 may have a second conductivity type. A second device isolation layer 204 and sacrificial patterns 272 may be formed on the second substrate 202 in the pixel array region APS (S210). The second device isolation layer 204 may be configured to electrically separate adjacent pixel transistors from each other. For example, the second device isolation layer 204 may be formed by etching a region of the second substrate 202 adjacent to the second front surface 202a and then filling the etched region with an insulating material.

The sacrificial patterns 272 may be configured to specify positions where the second vertical conductive lines 232 may be formed. For example, the sacrificial patterns 272 may be formed at positions overlapping one of a pair of source/drain regions of the dual conversion gain transistor and the gate electrode of the source follower transistor along the third direction D3. For example, the sacrificial patterns 272 may be formed by etching the second substrate 202 from the second front surface 202a to a required depth and then filling the etched region with a sacrificial material. The sacrificial material may be removed by wet etching. For example, the sacrificial material may include, for example, photoresist, silicon oxide, or silicon nitride.

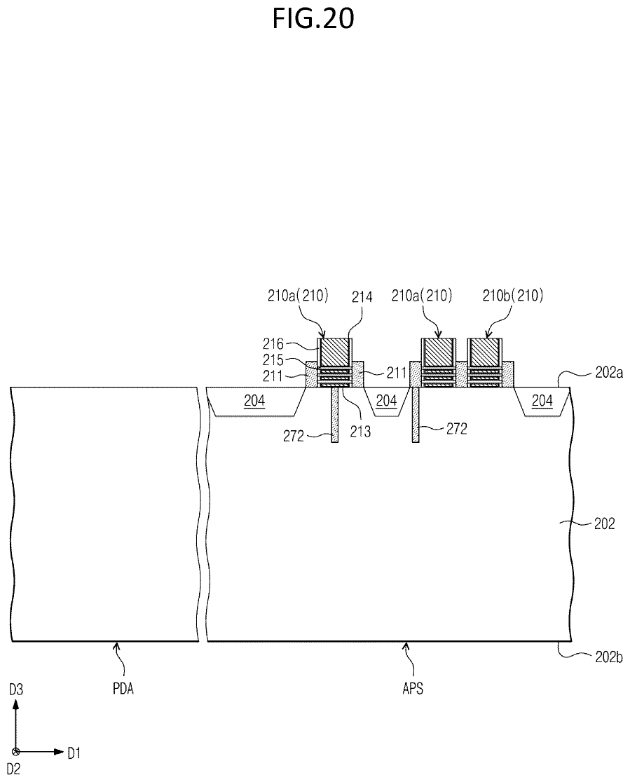

Referring to FIGS. 18 and 20, pixel transistors 210 may be formed on the second substrate 202 in the pixel array region APS (S220). The pixel transistors may be of the gate all-around type. Each of the pixel transistors 210 may include a first pixel source/drain region 211, a second pixel source/drain region 211, pixel channel regions 215, a pixel gate electrode 213, and a pixel gate insulating layer 214, and a pixel spacer 216.

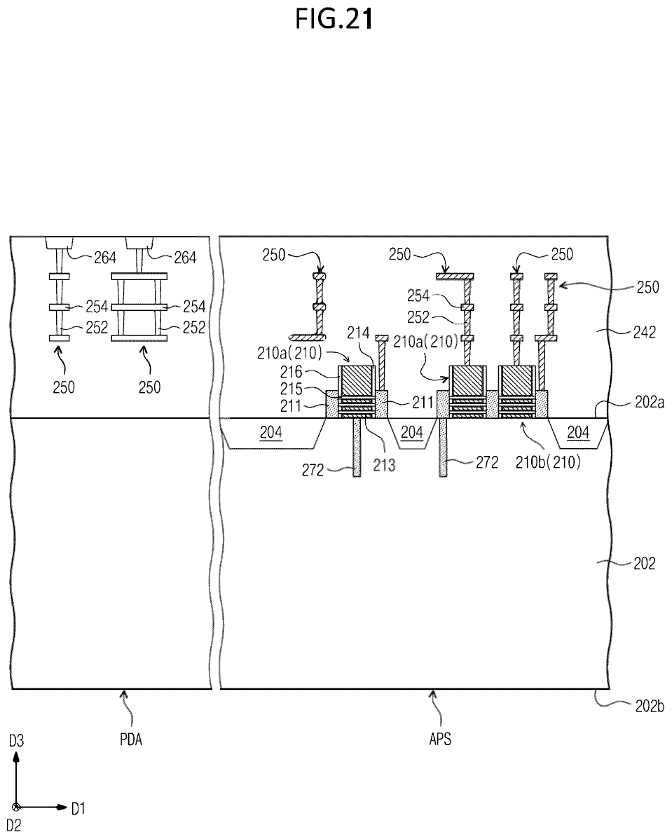

Referring to FIGS. 18 and 21, a third insulating layer 242, third conductive lines 250, and third pads 264 may be formed on the second front surface 202a (S230). For example, It may be repeated to form a portion of a third insulating layer 242 on the second front surface 202a, to form a third vertical conductive line 252 penetrating a portion of the third insulating layer 242 and a third horizontal conductive line 254 extending in the first direction D1 or in the second direction D2 on a portion of the third insulating layer 242, to form another part of the third insulating layer 242 to cover the third horizontal conductive lines 254. A third pad 264 may be formed on the third vertical conductive lines 252 located furthest from the second front surface 202a in the pad region PDA.

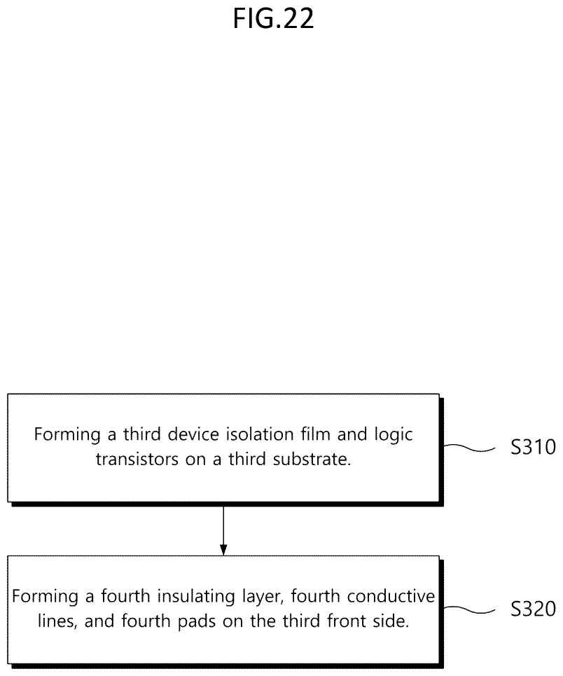

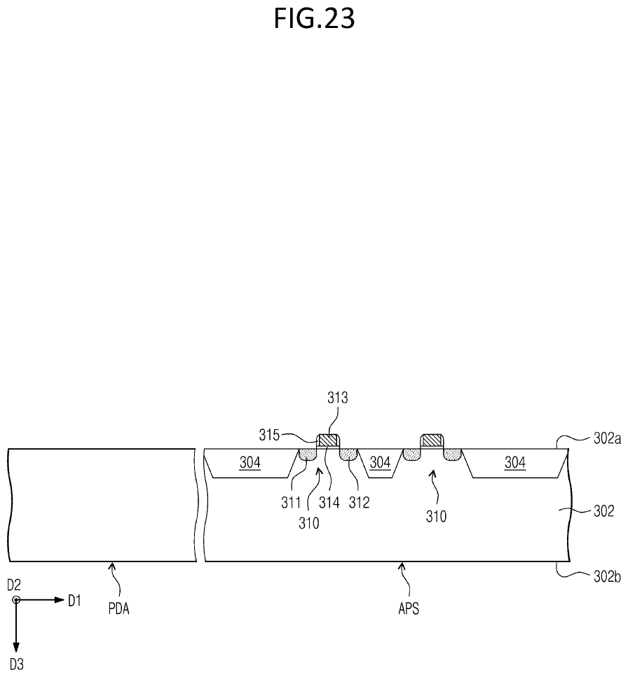

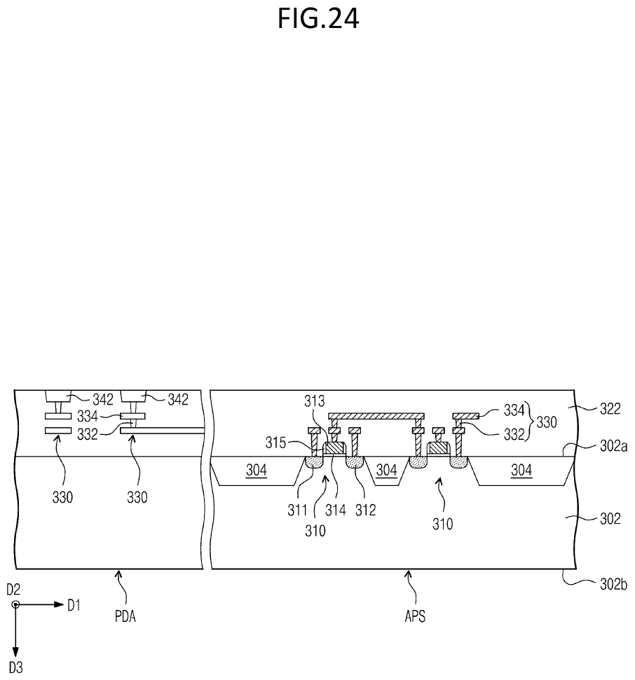

FIG. 22 is a flowchart for explaining the manufacturing method of the third layer of FIG. 10. FIGS. 23 and 24 are drawings for explaining the manufacturing method of FIG. 22. For brevity of explanation, content substantially the same as that described with reference to FIG. 10 may not be described.

Referring to FIGS. 22 and 23, a third substrate 302 may be provided. The third substrate 302 may include a pixel array region APS and a pad region PDA. The third substrate 302 may have a second conductivity type. A third device isolation layer 304 and logic transistors 310 may be formed on the third substrate 302 (S310). The third device isolation layer 304 may be configured to electrically separate adjacent logic transistors from each other. For example, the third device isolation layer 304 may be formed by etching a region of the third substrate 302 adjacent to the third front surface 302a and then filling the etched region with an insulating material.

Referring to FIGS. 22 and 24, a fourth insulating layer 322, fourth conductive lines 330, and fourth pads 342 may be formed on the third front surface 302a (S320). For example, it may be repeated to form a portion of the fourth insulating layer 322 on the third front 302a, to form a fourth vertical conductive line 332 penetrating a portion of the fourth insulating layer 322 and a fourth horizontal conductive line 334 extending in the first direction D1 or second direction D2 on a portion of the fourth insulating layer 322, to form another part of the fourth insulating layer 322 to cover the fourth horizontal conductive lines 334. The fourth pad 342 may be formed on the fourth vertical conductive lines 332 located furthest from the third front surface 302a in the pad region PDA.

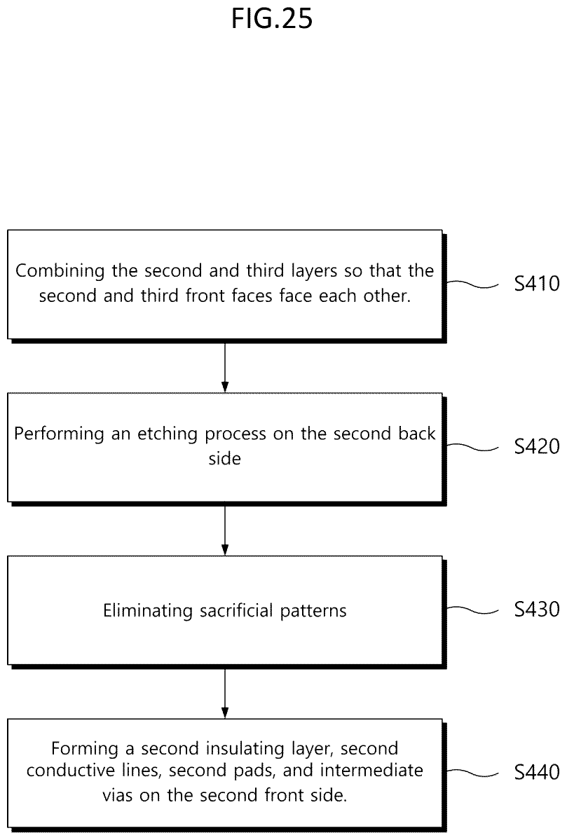

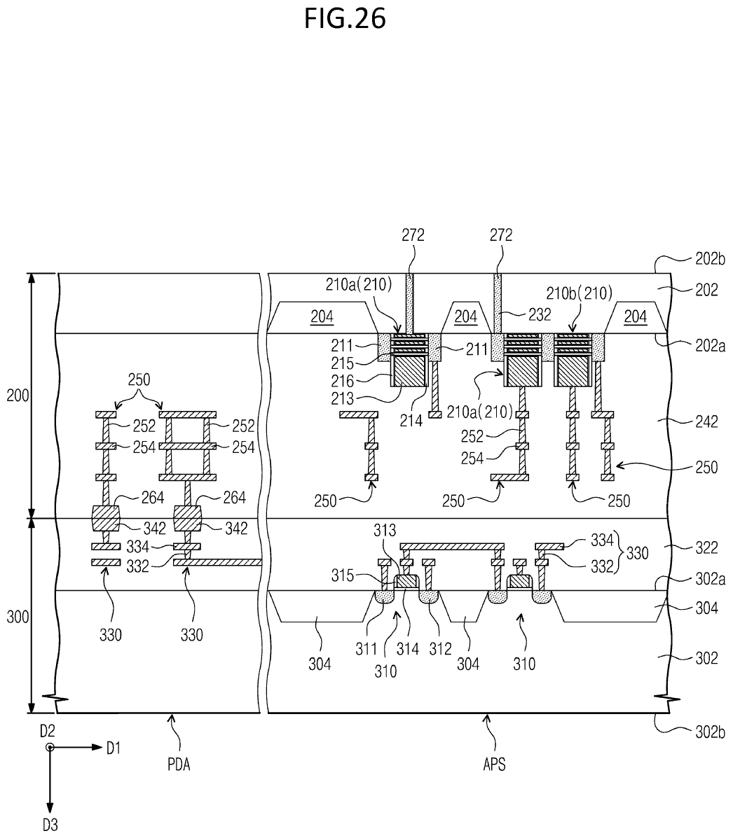

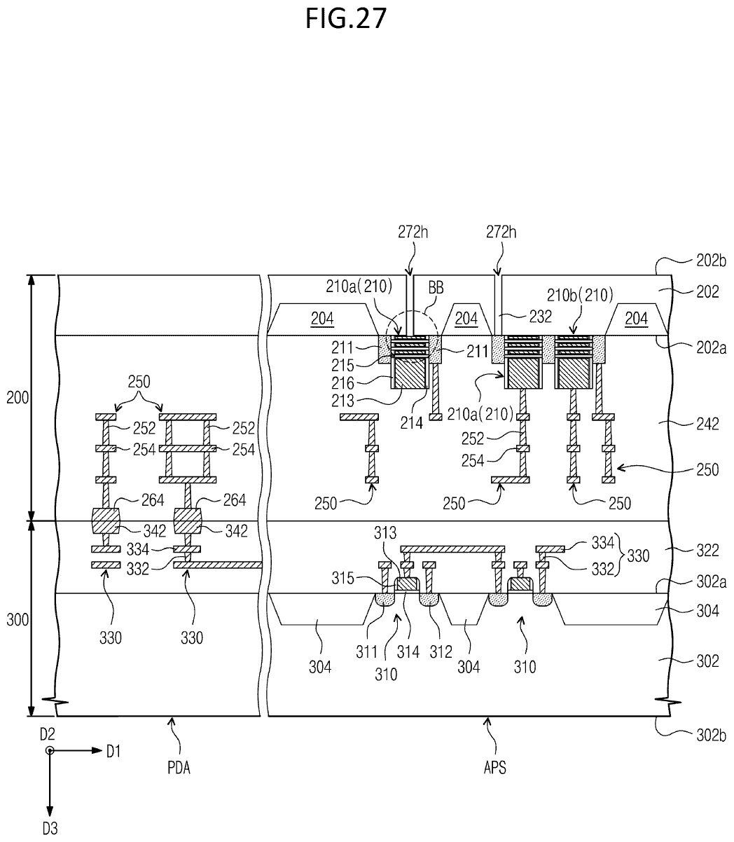

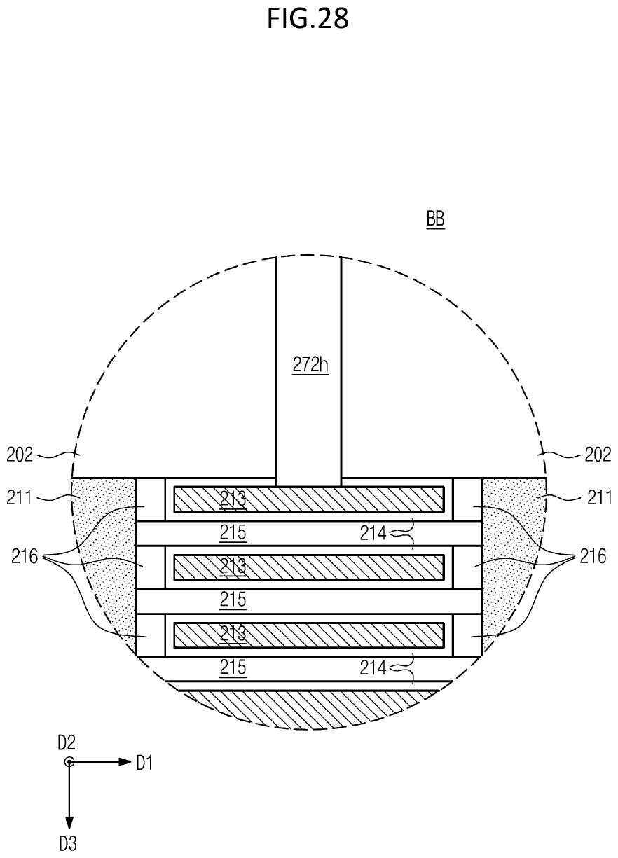

FIG. 25 is a flowchart for explaining a method of manufacturing the bonded second and third layers of FIG. 10. FIGS. 26, 27, and 29 are drawings for explaining the manufacturing method of FIG. 24. FIG. 28 is an enlarged view of portion BB of FIG. 27. For brevity of explanation, content substantially the same as that described with reference to FIG. 10 may not be described.

Referring to FIGS. 25 and 26, the second layer 200 and the third layer 300 may be combined so that the second front surface 202a and the third front surface 302a face each other (S410). The pads 264 and the fourth pads 342 may each form copper (Cu)—copper (Cu) bonding.

An etching process may be performed on the second back surface 202b to reduce the thickness of the second substrate 202 (S42). For example, the etching process on the second back surface 202b may be performed until the sacrificial patterns 272 are exposed.

Referring to FIGS. 25 to 27 and 28, the sacrificial patterns 272 may be removed (S430). For example, the sacrificial patterns 272 may be selectively removed by using an etching material having an etch selectivity with respect to the sacrificial patterns 272. The sacrificial patterns 272 may be removed to form holes 272h. The holes 272h may expose one of the pixel gate electrode 213 of the source follower transistor and the pixel source/drain regions 211 of the dual conversion gain transistor.

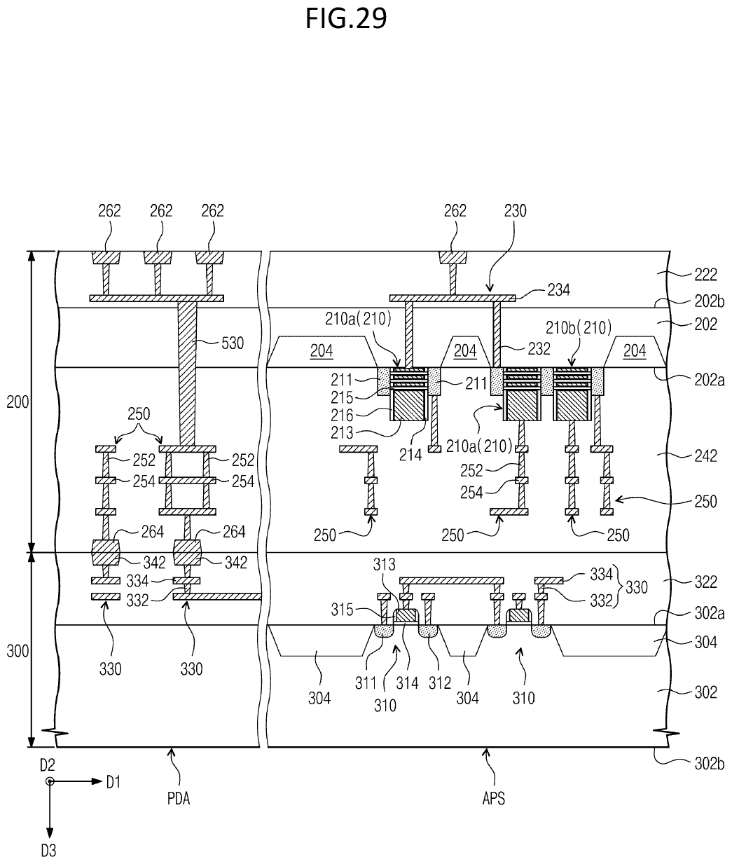

Referring to FIGS. 25 and 29, a second insulating layer 222, second conductive lines 230, second pads 262, and middle vias 530 may be formed on the second back surface 202b (S440). For example, after forming a portion of the second insulating layer 222 on the second back surface 202b, second vertical conductive lines 232 are formed penetrating a portion of the second insulating layer (S440). Second horizontal conductive lines 234 extending in the first direction D1 or the second direction D2 may be formed on a portion of the second insulating layer 222. Forming another part of the second insulating layer 222 on the part to cover the second horizontal conductive lines 234 may be repeated. Second vertical conductive lines 232 may be formed in the regions where the sacrificial patterns 272 have been removed. The second vertical conductive lines 232 may be electrically connected to the pixel gate electrode 213 of the source follower transistor and one of the pixel source/drain regions 211 of one phase of the dual conversion gain transistor. The second pad 262 may be formed on the second vertical conductive lines 232 located furthest from the second front surface 202a.

Before the second horizontal conductive line 234 immediately adjacent to the second back surface 202b may be formed, a middle via 530 penetrating the second substrate 202 may be formed in the pad region PDA. For example, the middle via 530 may be formed by forming a hole penetrating a portion of the second insulating layer 222, the second substrate 202, and a portion of the third insulating layer 242, and filling an electrically conductive material within the hole. The hole may expose the third horizontal conductive line 254 immediately adjacent to the second front surface 202a. In some example embodiments, an insulating layer may be formed on the side of the middle via 530. The middle via 530 may be electrically connected to the second horizontal conductive line 234 immediately adjacent to the second back surface 202b and the third horizontal conductive line 254 immediately adjacent to the second front surface 202a.

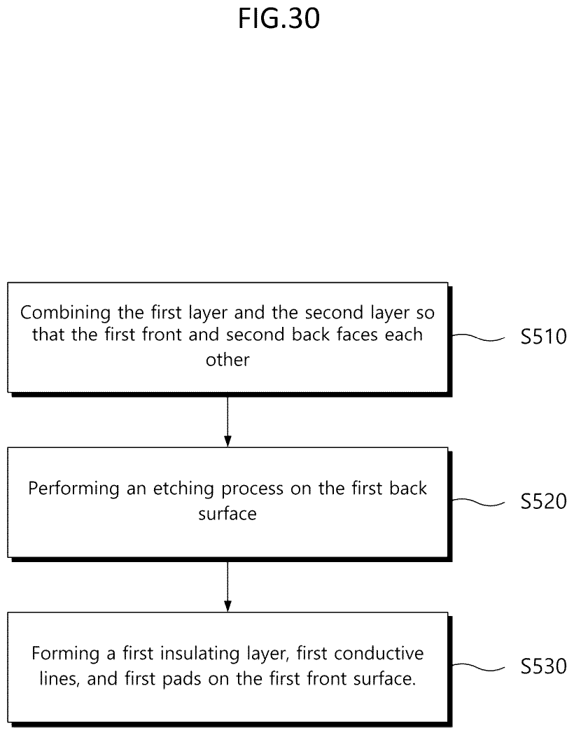

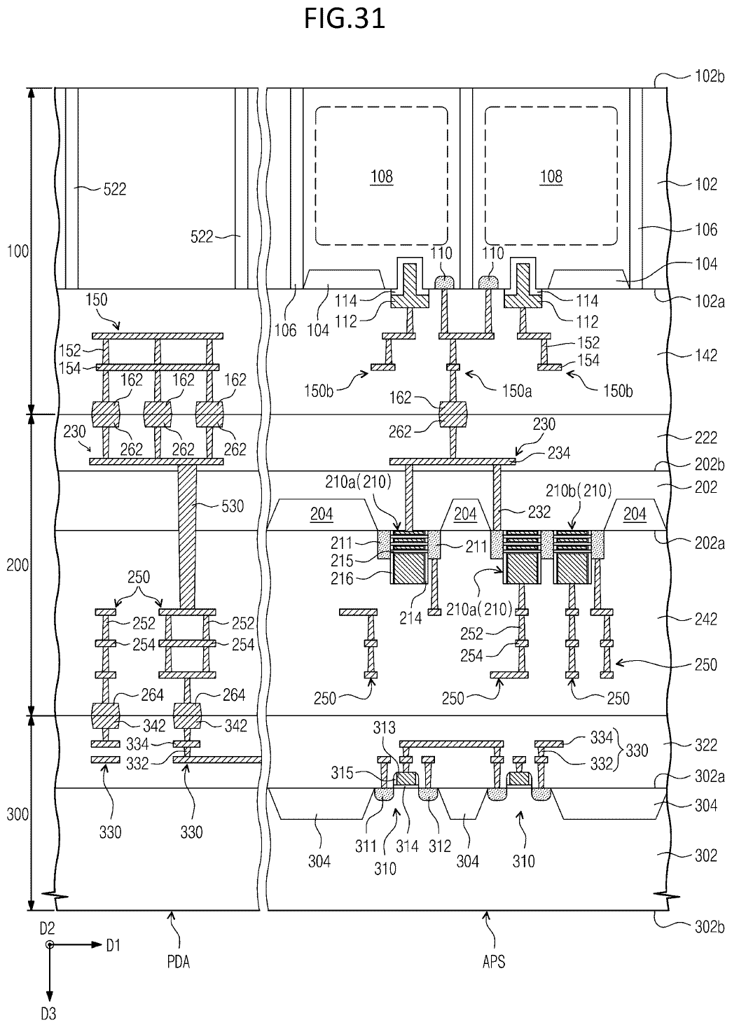

FIG. 30 is a flowchart for explaining a method of manufacturing the bonded first to third layers of FIG. 10. FIG. 31 is a diagram for explaining the manufacturing method of FIG. 30. For brevity of explanation, content substantially the same as that described with reference to FIG. 10 may not be described.

Referring to FIGS. 30 and 31, the first layer 100 and the second layer 200 may be combined so that the first front surface 102a and the second back surface 202b face each other. The first pads 162 and the second pads 262 may form copper (Cu)—copper (Cu) bonding (S510).

An etching process may be performed on the first back surface 102b to reduce the thickness of the first substrate 102 (S520). For example, the etching process on the first back surface 102b may be performed until the required thickness of the first substrate 102 may be obtained.

Referring to FIGS. 30 and 10, a main via 520, a signal pad 510, a color filter 132, and a micro lens 134 may be formed (S530). The main via 520 may be formed to penetrate the first substrate 102 in the pad region PDA. For example, the main via 520 may be formed by forming a hole penetrating a portion of the first substrate 102 and the first insulating layer 142 and then filling the hole with an electrically conductive material. The hole may expose the first horizontal conductive line 154 immediately adjacent to the first front surface 102a. In some example embodiments, an insulating layer may be formed on a side of the main via 520. The main via 520 may be electrically connected to the first horizontal conductive line 154 immediately adjacent to the first front surface 102a.

Signal pad 510 may be formed on main via 520. In some example embodiments, the signal pad 510 and the main via 520 may form a single structure. For example, the signal pad 510 may be formed by forming an electrically conductive material layer on the first back surface 102b when forming the main via 520 and then patterning the electrically conductive material layer.

A color filter 132 and a micro lens 134 may be formed on the first back surface 102b. The color filter 132 and micro lens 134 may be substantially the same as the color filter 132 and micro lens 134 described with reference to FIGS. 5 and 6.

According to the present disclosure, an image sensor with reduced (and/or minimized) size may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. An image sensor comprising:
a first layer including a first substrate having a first front surface and a first back surface opposite the first front surface, a floating diffusion region in the first substrate, a first pad, and a first conductive line connecting the floating diffusion region and the first pad; and
a second layer including a second substrate having a second front surface and a second back surface opposite the second front surface, pixel transistors on the second substrate, a second pad, and a second conductive line connecting one of the pixel transistors and the second pad,
wherein the second layer is bonded to the first layer, and
wherein the second conductive line passes through the second substrate and is electrically connected to a lower portion of the pixel transistor.

2. The image sensor of claim 1, wherein the second conductive line comprises a vertical conductive line extending along a direction parallel to a stacking direction of the first layer and the second layer, and a horizontal conductive line extending along a direction perpendicular to the vertical conductive line, and
wherein the vertical conductive line is directly adjacent to the one of the pixel transistors and passes through the second substrate.

3. The image sensor of claim 1, wherein the second conductive line is electrically connected to a gate electrode of the one of the pixel transistors.

4. The image sensor of claim 3, wherein the one of the pixel transistors is a source follower transistor.

5. The image sensor of claim 1, wherein the second conductive line is electrically connected to a drain region of the one of the pixel transistors.

6. The image sensor of claim 5, wherein one of the pixel transistors is a double conversion gain transistor.

7. The image sensor of claim 5, wherein the second layer further includes a third conductive line electrically connected to the drain region of the one of the pixel transistors on the second front surface of the second layer, and
wherein the third conductive line is electrically connected to a gate electrode of another one of the pixel transistors.

8. The image sensor of claim 1, wherein the second conductive line includes a vertical conductive line extending along a direction parallel to a stacking direction of the first layer and the second layer, and a horizontal conductive line extending along a direction perpendicular to the vertical conductive line,
wherein the vertical conductive line includes a first vertical conductive line passing through the second substrate and electrically connected to a gate electrode of the one of the pixel transistors, and a second vertical conductive line passing through the second substrate and electrically connected to a drain region of another one of the pixel transistors, and
wherein the first vertical conductive line and the second vertical conductive line are electrically connected to each other by the horizontal conductive line.

9. The image sensor of claim 8, wherein the second layer further includes a first insulating layer on the second back surface of the second substrate, and
wherein the horizontal conductive line is in the first insulating layer on the second back surface.

10. The image sensor of claim 8, wherein the second layer further includes a first insulating layer on the second front surface of the second substrate, and
wherein the first vertical conductive line and the second vertical conductive line are spaced apart from the first insulating layer.

11. The image sensor of claim 8, wherein the first vertical conductive line overlaps the gate electrode of the one of the pixel transistors along the direction parallel to the stacking direction of the first layer and the second layer, and
wherein the second vertical conductive line overlaps the drain region of the another one of the pixel transistors along the direction parallel to the stacking direction of the first layer and the second layer.

12. An image sensor comprising:
a pixel array including a plurality of pixels, wherein the plurality of pixels include a first pixel and a second pixel adjacent to each other,
wherein each of the first pixel and the second pixel includes a first layer and a second layer bonded to the first layer,
wherein the first layer includes a first substrate having a first front surface and a first back surface opposite the first front surface, a floating diffusion region in the first substrate, at least one first pad, and a first conductive line connecting the floating diffusion region and the at least one first pad,
wherein the second layer includes a second substrate having a second front surface and a second back surface opposite the second front surface, pixel transistors on the second substrate, a second pad, and a second conductive line connecting one of the pixel transistors and the second pad, and
wherein the second conductive line passes through the second substrate and is electrically connected to a lower portion of the one of the pixel transistors.

13. The image sensor of claim 12, wherein the floating diffusion region of the first pixel and the floating diffusion region of the second pixel are electrically connected to a same first pad from among the at least one first pad.

14. The image sensor of claim 12, wherein the floating diffusion region of the first pixel and the floating diffusion region of the second pixel are electrically connected to different first pads from among the at least one first pad.

15. The image sensor of claim 12, wherein the first conductive line includes a vertical conductive line extending along a direction parallel to a stacking direction of the first layer and the second layer, and at least one horizontal conductive line extending along a direction perpendicular to the vertical conductive line,
wherein the vertical conductive line includes a first vertical conductive line electrically connected to the floating diffusion region of the first pixel, and a second vertical conductive line electrically connected to the floating diffusion region of the second pixel, and
wherein the first vertical conductive line and the second vertical conductive line are electrically connected to a same horizontal conductive line from among the at least one horizontal conductive line.

16. An image sensor comprising a pixel array region and a pad region, wherein each of the pixel array region and the pad region includes a first layer and a second layer bonded to the first layer,
wherein in the pixel array region the first layer includes a first substrate having a first front surface and a first back surface opposite the first front surface, a floating diffusion region in the first substrate, a first pad, and a first conductive line connecting the floating diffusion region and the first pad,
wherein in the pixel array region the second layer includes a second substrate having a second front surface and a second back surface opposite the second front surface, pixel transistors on the second substrate, a second pad, and a second conductive line connecting one of the pixel transistors and the second pad, the second conductive line passing through the second substrate and being electrically connected to a lower portion of the pixel transistor, and
wherein in the pad region the first layer includes a main via penetrating the first substrate, and a signal pad on the main via.

17. The image sensor of claim 16, wherein each of the pixel array region and the pad region further includes a third layer bonded to the second layer,
wherein the third layer includes a third substrate having a third front surface, a third back surface opposite the third front surface, and logic transistors.

18. The image sensor of claim 17, wherein the logic transistors and the signal pad are electrically connected to each other.

19. The image sensor of claim 18, wherein in the pad region the second layer further includes a third conductive line on the second front surface of the second substrate, a middle via between the third conductive line and the second conductive line, and a third pad connected to an opposite side of the middle via with respect to the third conductive line, and
wherein the third layer further includes a fourth pad in contact with the third pad and a fourth conductive line connecting the fourth pad and the logic transistors.

20. The image sensor of claim 19, wherein in the pad region the first conductive line and the second conductive line are configured to have a grid shape.
